(19) United States
(12) Patent Application Publication
(10) Pub. No.: US 2006/0220014 A1
(43) Pub. Date: Oct. 5, 2006

(54) Liquid crystal display device and manufacturing method therefor

(75) Inventors: Naoto Hirano, Tokyo (JP); Daisuke Iga, Tokyo (JP); Kazuhide Yoshinaga, Kanagawa (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignees: NEC Corporation; NEC LCD Technologies, Ltd.

(21) Appl. No.: 11/375,127

(22) Filed: Mar. 15, 2006

(30) Foreign Application Priority Data
Mar. 15, 2005 (JP) 2005-073156

(51) Int. Cl. H01L 29/04

(52) U.S. Cl. 257/59

(57) ABSTRACT

To provide a liquid crystal display device in which capacity value of storage capacitance is large and manufacturing cost is low, and a manufacturing method thereof. A plurality of gate lines is provided on a pixel circuit substrate of a liquid crystal display device. Further, a TFT is provided to each pixel, and a drain line is connected with the drain, and a pixel electrode is connected with the source, and the gate line is connected with the gate electrode. Lower electrodes are made to extend from the gate line. In an area immediately above the lower electrodes connected with the n^{th} gate line from the drain line control circuit side, a pixel electrode coupled to the (n+1)^{th} gate line via the TFT is disposed. Thereby, storage capacitance is formed between the lower electrodes connected with the n^{th} gate line and the pixel electrode coupled to the (n+1)^{th} gate line.

### BACKGROUND OF THE INVENTION

1. Field of the Invention

The present invention relates to a liquid crystal display device using a thin film transistor as a drive element, and a manufacturing method thereof. In particular, the present invention relates to a liquid crystal display device in which each pixel has storage capacitance, and a manufacturing method thereof.

2. Description of Related Art

In an active matrix type liquid crystal display device, a pixel circuit substrate and a counter substrate are provided in parallel to each other with a certain distance, and liquid crystal is filled between these substrates. In the pixel circuit substrates, a plurality of gate lines (scan lines) extending in a direction parallel to each other, that is, a horizontal direction for example, and a plurality of drain lines (data lines) extending in a direction orthogonal to the extending direction of the gate lines, that is, a vertical direction for example, are provided on a transparent substrate for example, and a pixel is formed at each of the nearest contacts between the gate lines and the drain lines, and a pixel circuit is provided for each pixel. Each pixel circuit includes a pixel electrode and a thin film transistor (hereinafter referred to as TFT) for switching whether to connect a drain line to the pixel electrode. A drain electrode of the TFT is connected with a drain line, and a source electrode is connected with a pixel electrode, and a gate electrode is connected with a gate line. Further, in a non-display area (frame area) provided outside the display area of the pixel circuit substrate, a control circuit is provided to control potential of the gate lines and the drain lines. On the counter substrate, common electrodes are provided in the display area on the transparent substrate.

In order to make a liquid crystal display to have high image quality, it is important to stabilize potential of the pixel electrodes. Assuming that potential of a pixel electrode is Vₚ, the fluctuation amount is ΔVₚ, potential of a gate electrode is V_{g}, the fluctuation amount is ΔV_{g}, parasitic capacitance between a gate electrode (gate line) and a source electrode (pixel electrode) is C_{pc}, pixel capacitance between a pixel electrode and a counter electrode is C_{lc}, and storage capacitance added to a pixel electrode is Cₛₜ, the fluctuation amount ΔVₚ of pixel electrode potential is expressed by the following equation 1:

$$Δ {V}_{p} = \frac{{C}_{pc}}{{C}_{pc} + {C}_{1 c} + {C}_{st}} Δ {V}_{g} \qquad ( 1 )$$

FIG. 24 is a characteristic diagram showing an example of a driving voltage waveform when an N-type TFT is used as a TFT of a pixel circuit, where the horizontal axis shows time, and the vertical axis shows potential of each of a drain electrode, a gate electrode and a pixel electrode. Hereinafter, an exemplary method of driving a liquid crystal display device will be explained with reference to the equation 1 and FIG. 24. When gate voltage V_{g} is switched from a low level to a high level in a state where potential of a drain electrode (hereinafter referred to as drain voltage V_{d}) has a predetermined valued corresponding to image data, the TFT is conducted and the drain line is connected with the pixel electrode. Thereby, the pixel electrode potential Vₚ becomes equal to the drain voltage V_{d}, and charges depending on the drain voltage V_{d} are stored in the pixel electrode. However, when the gate voltage V_{g} is switched from a high level to a low level thereafter and the TFT becomes not to be conducted, the charges stored on the pixel electrode are redistributed to the parasitic capacitance C_{pc}, the pixel capacitance C_{lc} and the storage capacitance Cₛₜ, and the pixel electrode potential Vₚ fluctuates by ΔVₚ. This phenomenon is called field through.

In such a case, if the parasitic capacitance C_{pc} is large, ΔVₚ increases, whereby the pixel electrode potential Vₚ largely fluctuates. Since the voltage difference between the pixel electrode potential Vₚ and the common electrode potential V_{com} serves as driving voltage of the liquid crystal layer, the transmittance of the liquid crystal layer does not stabilize when ΔVₚ is large, so the display quality will deteriorates. Further, since the liquid crystal capacitance C_{lc} continues fluctuation corresponding to the leak current amount of the TFT, the display quality will further deteriorates.

As a liquid crystal display device becomes to have higher definition, that is, as display pixels become denser, fluctuation of the liquid crystal capacitance C_{lc} becomes larger as the parasitic capacitance C_{pc} increases, whereby stability of the pixel electrode potential Vₚ becomes more difficult. On the other hand, in order to secure display quality, stabilization of the pixel electrode potential Vₚ becomes more important. For stabilizing the pixel electrode potential Vₚ, reducing the leak current amount of the TFT and increasing the storage capacitance Cₛₜ are effective measures.

Conventionally, as means for reducing leak current amount of a TFT, there have been known a lightly doped drain (LDD) structure, a gate over-lapped drain (GOLD) structure and the like. Further, as a method of adding storage capacitance Cₛₜ, there has been known art to form storage capacitance by, using an active layer of TFT as lower electrode, forming upper electrodes in the same step as that of gate electrodes and a gate insulating film between an upper electrode and a lower electrode is used as a capacitance insulating film, as shown in the publication of Japanese Patent Application Laid-open No. 10-186401 (FIG. 1) (Patent Document 1).

In Patent Document 1, a polycrystalline silicon film (hereinafter referred to as p-Si film) is used as an active layer of a TFT. If a p-Si film is used instead of an amorphous silicon film (hereinafter referred to as a-Si film) as an active layer of a TFT constituting a drive element, that is, an element for a pixel circuit or a control circuit, of a liquid crystal display device, higher definition and higher image quality can be realized further. This is because a p-Si film has carrier (electron and hole) mobility several tens to several hundreds time of that of an a-Si film.

Further, in Patent Document 1, an a-Si film is formed on a glass substrate, and an excimer laser is irradiated to the a-Si film so as to melt the a-Si film to be crystallized to thereby form a p-Si film. Further, in such a low-temperature p-Si type TFT manufacturing step, a film of fine quality can be obtained by forming a p-Si film on a flat surface. Thereby, there is adopted a top gate type TFT in which a p-Si film is formed on a substrate and a gate insulating film and a gate electrode are formed above the p-Si film. Then, in Patent Document 1, the p-Si film which is an active layer, that is, a p-Si film in which P-type or N-type impurity is doped at high concentration so as to reduce electric resistance, is extended from the source region side so as to form a lower electrode. Further, in an area immediately above the lower electrode, an upper electrode is formed in the same step as that of a gate electrode, and by using a gate insulating film positioned between the upper electrode and the lower electrode as a capacitance insulating film, storage capacitance is formed.

However, in the liquid crystal display device described in Patent Document 1, ion doping for forming a p-Si film having low electric resistance as a source/drain region of the TFT must be performed before forming a gate electrode. Therefore, for the ion doping step, a photolithography step must be performed one more time. Further, in the ion doping step, since a gate electrode cannot be used as a mask, there is a problem that a source/drain region cannot be formed in a self-aligning manner. Note that if ion doping is performed after a step of forming a gate electrode, there is a problem that ions are difficult to reach the p-Si film used for the lower electrode since the upper electrode serves as a barrier, whereby the electric resistance of the p-Si film cannot be reduced. Further, if ion doping is performed after a p-Si film and a gate insulting film are formed, the withstand voltage of the gate insulating film drops due to implanted ion defect.

Further, if a p-Si film is used as an active layer as described in Patent Document 1, there is a problem that the withstand voltage of a capacitance insulating film of the storage capacitance further drops due to Si grain boundary protrusions of the p-Si film. In the art described in Patent Document 1, drop of the withstand voltage of the capacitance insulating film due to the Si grain boundary protrusions of the gate insulating film is improved by making the average crystal grain diameter of a part used as a lower electrode of the storage capacitance of the p-Si film, in the p-Si film, smaller than the average crystal grain diameter of a part corresponding to an area immediately below the gate electrode. However, size control of the Si grain boundary protrusions is difficult, and as long as the gate insulating film on the p-Si film is used as a storage capacitance insulating film, statistical drop of the withstand voltage is not avoidable.

In order to prevent the problems described above, for example, the publication of Japanese Patent Application Laid-open No. 10-133233 (FIG. 1) (Patent Document 2) discloses art in which a new storage capacitance insulating film is formed on a gate insulting film, and a laminated film of the gate insulating film and the storage capacitance insulting film is used as a capacitance insulting film of storage capacitance. According to the art described in Patent Document 2, it is possible to compensate for the drop of withstand voltage in the capacitance insulating film by forming a new film without any damage on the gate insulating film in which the withstand voltage has been dropped due to ion doping.

However, in the art described in Patent Document 2, a storage capacitance insulating film is formed separate from a gate insulating film, whereby the number of manufacturing steps and the manufacturing cost increase. Further, by laminating the gate insulating film and the storage capacitance insulating film, the distance between the lower electrode and the upper electrode in the storage capacitance becomes large consequently, whereby the capacity value of the storage capacitance decreases.

Further, an insulating film other than a gate insulating film, such as an interlayer insulating film for electrically separating a gate electrode and a drain electrode, may be used as a storage capacitance insulating film. Even in this case, however, if the interlayer insulating film is made thick so as to secure the withstand voltage between the lower electrode and the upper electrode of the storage capacitance, there is a problem that sufficient storage capacitance Cₛₜ cannot be obtained. In contrast, if the interlayer insulating film is made thin so as to secure sufficient storage capacitance Cₛₜ, sufficient withstand voltage cannot be secured. That is, it is impossible to realize sufficient withstand voltage and sufficient storage capacitance Cₛₜ at the same time.

In view of the above, for example, the publication of Japanese Patent Application Laid-open No. 2000-091585 (FIG. 1) (Patent Document 3) discloses art in which a dedicated lower electrode is formed separate from the active layer of a TFT, and on the lower electrode, a dedicated capacitance insulating film is formed separate from the gate insulating film of the TFT, and on the capacitance insulating film, an upper electrode extending from the source electrode is formed whereby storage capacitance is formed in an area outside an area immediately above the p-Si film.

However, the conventional art described above has the following problem. That is, in the art described in Patent Document 3, a dedicated lower electrode and a dedicated capacitance insulating film are formed so as to form storage capacitance, whereby the number of steps for forming a liquid crystal display device increases. As a result, the manufacturing cost of a liquid crystal display device increases.

### SUMMARY OF THE INVENTION

The present invention is developed in view of the problems described above. It is therefore an object of the present invention to provide a liquid crystal display device in which capacity value of storage capacitance is large and the manufacturing cost is low, and a manufacturing method thereof.

A liquid crystal display device according to the present invention, having a plurality of pixels, comprises: a pixel circuit substrate; a counter substrate; and a liquid crystal layer disposed between the pixel circuit substrate and the counter substrate. The pixel circuit substrate includes: a substrate; a transistor provided for each pixel on the substrate; a lower electrode provided in an area outside an area immediately above an active layer of the transistor; an insulating film provided so as to cover the lower electrode; and a pixel electrode provided in an area including an area immediately above the lower electrode on the insulating film and connected with one of a source and a drain of the transistor, and storage capacitance is formed between the lower electrode and the pixel electrode.

In the present invention, a lower electrode of storage capacitance is provided separately from an active layer of the transistor, so there is no need to utilize a gate insulating film of the transistor as a capacitance insulating film of the storage capacitance, whereby it is possible to increase the capacity value of the storage capacitance. Further, in the present invention, it is possible to form a capacitance insulating film of storage capacitance by using an insulating film which serves as the base of a pixel electrode, and to form an upper electrode of the storage capacitance by using the pixel electrode. Thereby, there is no need to provide a special step for forming a capacitance insulating film and an upper electrode, so the manufacturing cost is low.

Further, the active layer is preferably formed of polycrystalline silicon. Thereby, it is possible to improve mobility of carrier in a transistor to thereby make images to have higher quality.

Further, the pixel circuit substrate may include: a plurality of data lines, extending in one direction, connected with another one of the source and the drain of the transistor; and a plurality of gate lines, extending in a direction crossing the one direction, connected with a gate electrode of the transistor, and the pixel electrode, which is provided in an area including an area immediately above the lower electrode and storage capacitance is formed between it and the lower electrode, may be connected with one of the source and the drain of the transistor in which a gate line, other than the gate line with which the lower electrode is connected, is connected with a gate electrode thereof. Thereby, it is possible to apply the same potential as that of a gate electrode not selected as the lower electrode.

Alternatively, the pixel circuit substrate may have wiring, extending in one direction, connected with the lower electrode. Thereby, it is possible to control potential of the lower electrode independent of potential of the gate line, which improves freedom in driving.

Further, it is preferable that the lower electrode and the gate electrode of the transistor be formed such that the same conductive film is patterned. Thereby, it is possible to further reduce the manufacturing cost.

Further, it is preferable that a dented part be formed in a part corresponding to an area immediately above the lower electrode in the insulating film, and a part corresponding to an area immediately above the lower electrode in the pixel electrode be provided at the bottom of the dented part. Thereby, the capacitance insulating film of the storage capacitance can be made thinner, whereby it is possible to increase the capacity value.

The insulating film may include: an interlayer insulating film, provided so as to cover the gate electrode of the transistor, on which the data line connected with the other one of the source and the drain of the transistor is disposed; and a planar film, provided so as to cover the data line on the interlayer insulating film, on which the pixel electrode is disposed, and the dented part may be formed through the planar film down to the middle of the interlayer insulating film.

The interlayer insulating film may include a lower layer and an upper layer formed on the lower layer, and the dented part may be formed through the planar film and the upper layer but not through the lower layer. In such a case, it is preferable that the dented part be formed by etching, and the etching rate of the upper layer in the etching be twice or more of the etching rate of the lower layer in the etching. Thereby, it is possible to etch the upper layer by using the lower layer as an etching stopper film.

Further, it is preferable that the planar film be formed of an organic material, and the insulating film be disposed between the interlayer insulating film and the planar film, and include a protective insulating film made of an inorganic material. Thereby, it is possible to improve humidity resistance of the liquid crystal display device.

Further, the pixel electrode may be formed of a transparent conductive material. Thereby, a liquid crystal display device of a transparent type is realized. In such a case, it is preferable that a plurality of apertures be formed in the lower electrode. Thereby, it is possible to increase the amount of transmitted light of the whole pixel circuit substrate without decreasing the capacity value of the storage capacitance largely.

Further, at least the surface of the pixel electrode may be formed of a conductive material reflecting visible light. Thereby, a liquid crystal display device of a reflection type is realized. In such a case, it is preferable that a plurality of apertures be formed in the lower electrode, and irregularities reflecting the shape of the lower electrode be formed on the top face of a part corresponding to an area immediately below the pixel electrode of the insulating film. Thereby, it is possible to form irregularities on the top face of the insulating film without a special step so as to reflect light diffusely.

The pixel electrode may include a transmission region made of a transparent conductive material and a reflection region made of a conductive material in which at least the surface thereof reflects visible light. Thereby, a liquid crystal display device of a translucent type is realized. In such a case, it is preferable that a plurality of apertures be formed in an area immediately below the reflection region in the lower electrode, and irregularities reflecting the shape of the lower electrode be formed on the top face of a part of the insulating film corresponding to an area immediately below the reflection region of the pixel electrode of the insulating film.

A method of manufacturing a liquid crystal display device according to the present invention comprises the steps of: producing a pixel circuit substrate; producing a counter substrate; and forming a liquid crystal layer between the pixel circuit substrate and the counter substrate. The step of producing the pixel circuit substrate includes the steps of: forming a semiconductor layer locally on the substrate; forming a gate insulating film so as to cover the semiconductor layer; forming a conductive film on the gate insulating film and patterning the conductive film to thereby form a gate electrode and a lower electrode; introducing impurity into the semiconductor layer so as to form an active layer, and forming a transistor consisting of the active layer, the gate insulating film and the gate electrode; forming an insulating film so as to cover the gate electrode and the lower electrode; and forming a pixel electrode so as to be connected with one of a source and a drain of the transistor in an area including an area immediately above the lower electrode on the insulating film.

### Effects of the Invention

According to the present invention, it is possible to obtain a liquid crystal display device in which the capacity value of the storage capacitance is large and the manufacturing cost is low.

### BRIEF DESCRIPTION OF THE DRAWINGS

FIG. 1 is a plan view showing a pixel circuit substrate of a liquid crystal display device according to a first embodiment of the present invention;

FIG. 2A is a partially enlarged plan view showing an area 100 in FIG. 1 by enlarging it, and FIG. 2B is a cross-sectional view taken along the line A-A′ in FIG. 2A;

FIG. 3A is a partially enlarged plan view showing a pixel circuit substrate of a liquid crystal display device according to a second embodiment of the present invention, and FIG. 3B is a cross-sectional view taken along the line A-A′ in FIG. 3A;

FIG. 4A is a partially enlarged plan view showing a pixel circuit substrate of a liquid crystal display device according to a third embodiment of the present invention, and FIG. 4B is a cross-sectional view taken along the line A-A′ in FIG. 4A;

FIG. 5 is a plan view showing a pixel circuit substrate of a liquid crystal display device according to a fourth embodiment of the present invention;

FIG. 6A is a partially enlarged plan view showing the area 100 in FIG. 5 by enlarging it, and FIG. 6B is a cross-sectional view taken along the line A-A′ in FIG. 6A;

FIG. 7 is a plan view showing a pixel circuit substrate of a liquid crystal display according to a fifth embodiment of the present invention;

FIG. 8A is a partially enlarged plan view showing the area 100 in FIG. 7 by enlarging it, and FIG. 8B is a cross-sectional view taken along the line A-A′ in FIG. 8A;

FIG. 9 is a plan view showing a pixel circuit substrate of a liquid crystal display device according to a sixth embodiment;

FIG. 10A is a plan view showing the area 100 in FIG. 9 by enlarging it, and FIG. 10B is a cross-sectional view taken along the line A-A′ in FIG. 10A;

FIG. 11 is a plan view of a pixel circuit substrate of a liquid crystal display device according to a seventh embodiment of the present invention;

FIG. 12A is a partially enlarged plan view showing the area 100 in FIG. 11 by enlarging it, and FIG. 12B is a cross-sectional view taken along the line B-B′ shown in FIG. 12A;

FIG. 13 is a plan view showing a pixel circuit substrate of a liquid crystal display device according to an eighth embodiment of the present invention;

FIG. 14A is a partially enlarged plan view showing the area 100 in FIG. 13 by enlarging it, and FIG. 14B is a cross-sectional view taken along the line B-B′ in FIG. 14A;

FIG. 15A is a plan view showing a method of manufacturing the liquid crystal display device according to a ninth embodiment of the present invention, and FIG. 15B is a cross-sectional view taken along the line A-A′ in FIG. 15A;

FIG. 16A is a plan view showing a method of manufacturing the liquid crystal display device according to the present embodiment, and FIG. 16B is a cross-sectional view taken along the line A-A′ in FIG. 16A, showing the next step of FIGS. 15A and 15B;

FIG. 17A is a plan view showing a method of manufacturing the liquid crystal display device according to the present embodiment, and FIG. 17B is a cross-sectional view taken along the line A-A′ in FIG. 17A, showing the next step of FIGS. 16A and 16B;

FIG. 18A is a plan view showing a method of manufacturing the liquid crystal display device according to the present embodiment, and FIG. 18B is a cross-sectional view taken along the line A-A′ in FIG. 18A, showing the next step of FIGS. 17A and 17B;

FIG. 19A is a plan view showing a method of manufacturing the liquid crystal display device according to the present embodiment, and FIG. 19B is a cross-sectional view taken along the line A-A′ in FIG. 19A, showing the next step of FIGS. 18A and 18B;

FIGS. 20A and 20B are cross-sectional view showing a method of forming an LDD region in a first modification of the ninth embodiment of the present invention in the order to steps;

FIG. 21 is a cross-sectional view showing a method of forming an LDD region in a second modification of the ninth embodiment of the present invention;

FIGS. 22A, 22B and 22C are cross-sectional views showing a method of patterning a planar film in a third modification of the ninth embodiment in the order of steps;

FIG. 23 is a graph, in which the horizontal axis shows flow rate of N₂ gas and the vertical axis shows etching rate, showing an example of influence affected by NH₃ gas flow rate and N₂ gas flow rate on the etching rate of an SiN film after deposition when the SiN film is deposited by the PCVD method; and

FIG. 24 is a graph, in which the horizontal axis shows time and the vertical axis shows potential of each of a drain electrode, a gate electrode and a pixel electrode, showing an example of driving voltage waveform when an N-type TFT is used as a TFT of a pixel circuit.

### DESCRIPTION OF PREFERRED EMBODIMENTS

Hereinafter, embodiments of the present invention will be explained specifically with reference to the accompanying drawings. First to eighth embodiments shown below are embodiments of liquid crystal display devices, and ninth to sixteenth embodiments are embodiments of manufacturing methods of the liquid crystal display devices according to the first to eighth embodiments, respectively. Note that in the first to sixteenth embodiments, same components are denoted by same reference numerals.

### First Embodiment

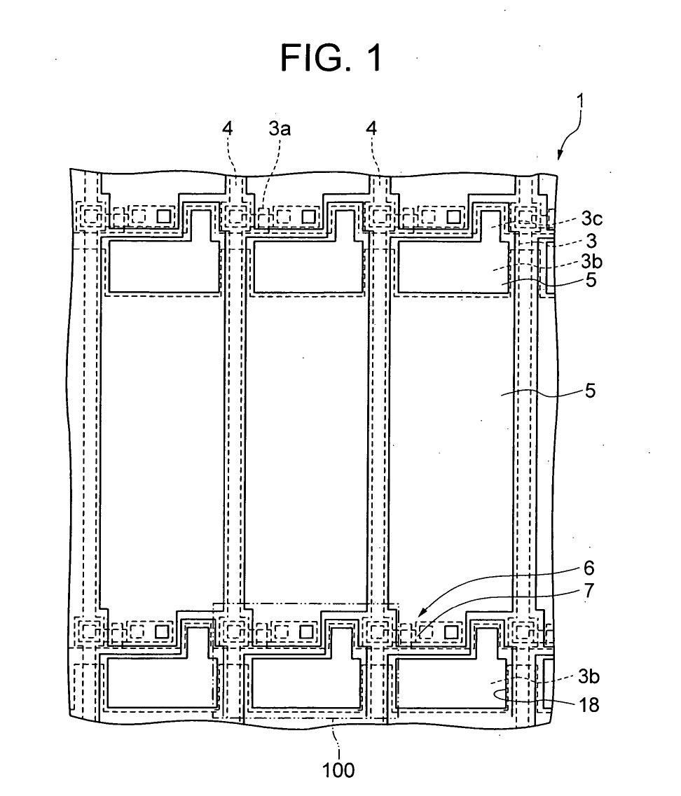

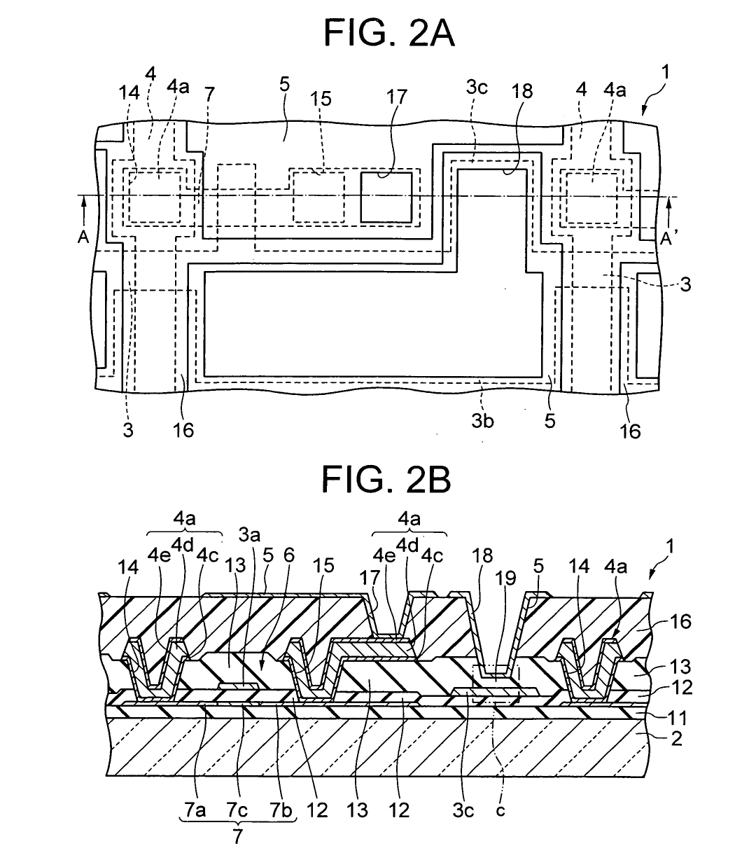

First, a first embodiment of the present invention will be explained. FIG. 1 is a plan view showing a pixel circuit substrate of a liquid crystal display device according to the present embodiment. FIG. 2A is a partially enlarged plan view showing an area 100 in FIG. 1 by enlarging it, and FIG. 2B is a sectional view taken along the line A-A′ in FIG. 2A. Note that in FIG. 1, only area corresponding to three pixels such as red (R), green (G) and blue (B) and the surrounding area in the display area of the pixel circuit substrate is shown.

As shown in FIG. 1, the liquid crystal display device according to the present embodiment is so configured that the pixel circuit substrate 1 and a counter substrate (not shown) are provided in parallel with a distance to each other, and liquid crystal (not shown) is filled in between the both substrates so as to form a liquid crystal layer. On the surface of a side facing the pixel circuit substrate 1 of the counter substrate, common electrodes are provided.

Further, the pixel circuit substrate 1 is provided with a transparent glass substrate 2 (see FIG. 2B). On the surface facing the counter substrate of the glass substrate 2, there are provided a plurality of gate lines 3 extending in one direction, that is, a horizontal direction for example, and a plurality of drain lines (data lines) 4 extending in a direction crossing the one direction, that is, a vertical direction for example. Note that the horizontal direction and the vertical direction mentioned above are the horizontal direction and the vertical direction in the display screen of this liquid crystal display device, and do not necessarily correspond to the direction of gravity. The horizontal direction and the vertical direction correspond to a lateral direction and a longitudinal direction in FIG. 1. Further, in a non-display area located on the left side in the lateral direction in the figure of the pixel circuit substrate 1, a gate line control circuit (not shown) for controlling potential of the gate lines 3 is provided, and in a non-display area located on the upper side in the longitudinal direction in the figure of the pixel circuit substrate 1, a drain line control circuit (not shown) for controlling potential of the drain lines 4 is provided. Further, a pixel is provided for each of the most nearby points between the gate lines 3 and the drain lines 4. Thereby, in the liquid crystal display device of the present embodiment, a plurality of pixels are aligned in a matrix.

At each pixel, a pixel electrode 5 made of a transparent conductive material such as ITO (indium tin oxide film) is provided, and also a TFT (thin film transistor) 6 for switching whether to connect the drain line 4 to the pixel electrode 5 is provided. The TFT 6 is provided with an active layer 7 consisting of a p-Si film (polycrystalline silicon film). One end part of the active layer 7 forms a source region of the TFT 6, and the other end part thereof forms a drain region, and a region between the source region and the drain region forms a channel region. The drain region is connected with the drain line 4, and the source region is connected with the pixel electrode 5. In an area immediately above the channel region of the TFT 6, a gate electrode 3a extending in a direction from the gate line 3 to the drain line control circuit is provided.

The gate line 3 is connected with lower electrodes 3b and 3c. The lower electrode 3b extends in a direction opposite the direction that the gate electrode 3a extends from the gate line 3, that is, in a direction away from the drain line control circuit, and the length in the horizontal direction is almost equal to the length of the pixel. Therefore, the lower electrodes 3b and 3c connected with the n^{th} gate line 3 counted from the drain line control circuit side are disposed in an area immediately below the pixel electrode 5 connected with the (n+1)^{th} gate line via the TFT 6. That is, viewed from a direction vertical to the surface of the glass substrate 2 (hereinafter referred to as in a plan view), the lower electrodes 3b and 3c of the n^{th} pixel counted from the drain line control circuit side and the pixel electrode 5 of the (n+1)^{th} pixel are superposed. Thereby, storage capacitance C is formed between the lower electrodes 3b and 3c of the nth pixel and the pixel electrode 5 of the (n+1)^{th} pixel.

Hereinafter, the TFT 6 and the surrounding part of each pixel will be explained. As shown in FIGS. 2A and 2B, in the pixel circuit substrate 1, a base insulating film 11 made of silicon oxide (hereinafter referred to as SiO) having a thickness of 300 nm, for example, is provided on the glass substrate 2. On the base insulating film 11, an active layer 7 made of p-Si having a thickness of 50 nm, for example, is provided. One end part of the active layer 7 forms a drain region 7a, and the other end part thereof forms a source region 7b, and a region between the drain region 7a and the source region 7b forms a channel region 7c. The drain region 7a and the source region 7b are filled with N-type impurity. Further, a gate insulating film 12 made of SiO having a thickness of 100 nm, for example, is provided all over the base insulating film 11 so as to cover the active layer 7.

On the gate insulating film 12, the gate line 3 made of molybdenum (Mo) having a thickness of 300 nm for example, the gate electrode 3a and the lower electrodes 3b and 3c are provided. The gate line 3, the gate electrode 3a and the lower electrodes 3b and 3c are formed integrally with a patterned single continuous film. That is, the gate line 3 extends linearly in a horizontal direction (lateral direction in the figure). Further, the gate electrode 3a extends from the gate line 3 in a direction toward the drain line control circuit (upper side in the longitudinal direction of the figure) and reaches an area immediately above the channel region 7c of the active layer 7. Further, the lower electrode 3b extends from the gate line 3 in a direction away from the drain line control circuit (lower side in the longitudinal direction of the figure), and the length of the lower electrode 3b in a horizontal direction is almost equal to the length of a pixel. Further, the lower electrode 3c extends from the gate line 3 in a direction toward the drain line control circuit (upper side in the longitudinal direction of the figure) and disposed on an area immediately above the area between the active layer 7. The lower electrodes 3b and 3c are disposed in an area outside the area immediately above the active layer 7.

All over the gate insulating film 12, there is provided an interlayer insulating film 13 made of SiO having a thickness of 400 nm, for example, so as to cover the gate line 3, the gate electrode 3a and the lower electrodes 3b and 3c. In a part of an area immediately above the drain region 7a of the active layer 7 in the interlayer insulating film 13, a drain connecting hole 14 is formed through the interlayer insulating film 13 and the gate insulating film 12, and in a part of an area immediately above the source region 7b, a source connecting hole 15 is formed through the interlayer insulating film 13 and the gate insulating film 12.

On the interlayer insulating film 13, there are provided a drain line 4, a drain electrode 4a and a source electrode 4b. The drain line 4, the drain electrode 4a and the source electrode 4b consist of a three-layered film in which an Mo film 4c of 50 nm thickness, an aluminum (Al) film 4d of 300 nm thickness and an Mo film 4e of 100 nm thickness are laminated in this order from the glass substrate 2 side. The drain line 4 extends linearly in a vertical direction. The drain electrode 4a is a part corresponding to the drain connecting hole 14 in the drain line 4, and is formed on the side face and the bottom face of the drain connecting hole 14 and is connected with the drain region 7a of the active layer 7. Further, the source electrode 4b is spaced apart from the drain line 4 and the drain electrode 4a, and is formed in an area including the source connecting hole 15. A part of the source electrode 4b is formed on the side face and the bottom face of the source connecting hole 15, and is connected with the source region 7b of the active layer 7. The remaining part of the drain electrode 4b is formed on the interlayer insulating film 13.

All over the interlayer insulating film 13, there is provided a planar film 16 made of a photosensitive organic material having a thickness of 2 to 3 μm. The top face of the planar film 16 does not reflect the shape of the structure of the lower layer side thereof, and is flat. In a part of an area immediately above a part of the interlayer insulating film 13 of the source electrode 4b in the planar film 16, a pixel electrode connecting hole 17 is formed through the planar film 16. Further, in an area immediately above the lower electrodes 3b and 3c of the planar film 16 and the interlayer insulating film 13, a storage capacitance hole 18 is formed through the planar film 16 in a dented shape cut into the upper part of the interlayer insulating film 13. The thickness of the interlayer insulating film 13 remaining at the bottom of the storage capacitance hole 18 is, for example, 100 nm. The whole thickness of the interlayer insulating film 13 is 400 nm for example, which means the storage capacitance hole 18 is formed in the interlayer insulating film 13 at the depth of 300 nm for example. The storage capacitance hole 18 is formed so as to include an area immediately above the lower electrodes 3b and 3c. Therefore, in a planar view, it is shaped such that a relative small rectangle part, corresponding to an area immediately above the lower electrode 3c and a part adjacent the lower electrode 3 of the gate line 3, extends toward the drain line driving circuit from a relatively large rectangle part corresponding to an area immediately above the lower electrode 3b and a part adjacent the lower electrode 3b of the gate line 3.

On the planar film 16, there is provided a pixel electrode 5 made of ITO having a thickness of 100 nm for example. The pixel electrode 5 is provided in an area including the pixel electrode connecting hole 17, so it is provided on the side face and the bottom face of the pixel electrode connecting hole 17 and is connected with the source electrode 4b on the bottom face of the pixel electrode connecting hole 17. Further, the pixel electrode 5 is not formed in an area immediately above the lower electrodes 3b and 3c of the pixel to which the pixel electrode 5 belongs, that is, the lower electrodes 3b and 3c with which the pixel electrode 5 is connected via the TFT 6. Instead, the pixel electrode 5 extends to an area immediately above the lower electrodes 3b and 3c of a pixel adjacent the drain line control circuit side (upper side in the longitudinal direction of the figure), viewed from the pixel. On the other hand, in an area immediately above the lower electrodes 3b and 3c of the pixel to which the pixel electrode 5 belongs, the pixel electrode 5 of a pixel adjacent the side apart from the drain line control circuit (lower side of the longitudinal direction of the figure), viewed from the pixel, extends.

Next, operation of a liquid crystal display device according to the embodiment configured as described above will be explained. In the liquid crystal display device according to the present embodiment, storage capacitance C is formed between the lower electrodes 3b and 3c formed to the n^{th} pixel from the drain line control circuit side and the pixel electrode 5 disposed on the bottom face of the storage capacitance hole 18 formed in an area immediately above the lower electrodes 3b and 3c, that is, the pixel electrode 5 formed to the (n+1)^{th} pixel. Here, the pixel electrode 5 formed to the (n+1)^{th} pixel serves as an upper electrode of the storage capacitance C, and the thinned part positioned at the bottom of the storage capacitance hole 18 in the interlayer insulating film 13 serves as an capacitance insulating film 19 of the storage capacitance C. Thereby, storage capacitance is added to the pixel electrode 5. Further, at this time, it is possible to apply same potential as the gate electrode of a pixel not selected (e.g., (n+1)^{th} pixel), that is, low level potential for example, to the lower electrode of the selected pixel (e.g., n^{th} pixel).

Next, effects of the present embodiment will be explained. In the present embodiment, the storage capacitance C is arranged in an area outside an area immediately above the active layer 7. Therefore, even if a p-Si film having high carrier mobility is formed as the active layer 7, the withstand voltage of the capacitance insulating film of the storage capacitance C will not be lowered due to grain boundary protrusions of the p-Si film. Therefore, by using a p-Si film as the active layer 7, it is possible to realize higher definition and higher quality of the display image, and to improve capacity value of the storage capacitance C by making the capacitance insulating film 19 to be thinner.

Further, in the present embodiment, since the lower electrode of the storage capacitance C is provided separate from the active layer 7 of the TFT 6, there is no need to use the gate insulating film 12 of the TFT 6 as the capacitance insulating film 19 of the storage capacitance C. Therefore, there is no such a problem that the withstand voltage of a capacitance insulating film is lowered by filling impurity to an active layer or a gate electrode cannot be used as a mask when filling impurity, as in the case of using a gate insulating film as a capacitance insulating film. Further, since the thickness of the capacitance insulating film 19 of the storage capacitance C can be selected without being limited by the thickness of the gate insulating film 12 of the TFT 6, it is possible to increase the capacity value of the storage capacitance C.

Further, in the present embodiment, since the storage capacitance hole 18 is formed down to the middle of the interlayer insulating film 13, the interlayer insulating film 13 positioned at the bottom of the storage capacitance hole 18 becomes a thin film. Thereby, the thickness of the capacitance insulating film 19 of the storage capacitance C is not limited by the thickness of the interlayer insulating film 13, and it is possible to increase the capacity value of the storage capacitance C.

Further, in the present embodiment, since a transparent pixel electrode is used as an upper electrode of the storage capacitance C, the transmitted light will never be shielded by the upper electrode. Thereby, the aperture ratio of the liquid crystal display device can be improved. As described above, it is possible to both simplify the manufacturing process and improve the display quality according to the present embodiment.

Note that as the pixel electrode 5, a transparent conductive film mainly made of zinc oxide (ZnO) may be provided instead of an ITO film. This leads to a reduction in the material cost of the pixel electrodes.

### Second Embodiment

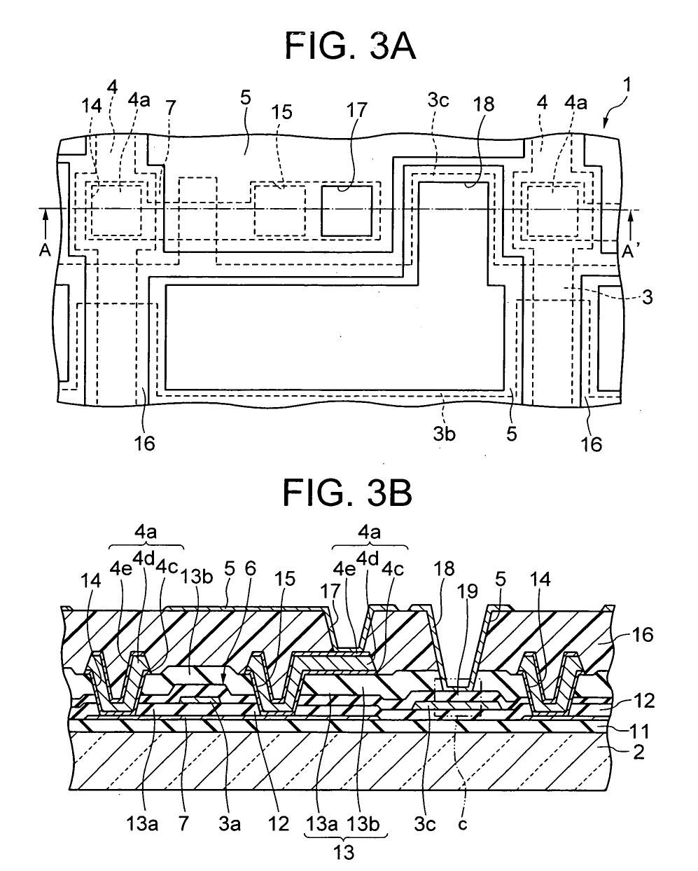

Next, a second embodiment of the present invention will be explained. FIG. 3A is a partially enlarged plan view showing a pixel circuit substrate of a liquid crystal display device according to the present embodiment, and FIG. 3B is a cross-sectional view taken along the line A-A′ in FIG. 3A. The area shown in FIG. 3A corresponds to the area 100 in FIG. 1 of the first embodiment.

As shown in FIG. 3A, the planar structure of the liquid crystal display device according to the present embodiment is same as that shown in FIG. 2A. As shown in FIG. 3B, the present embodiment is different from the first embodiment in that the interlayer insulating film 13 is in a double-layered structure. In the present embodiment, the interlayer insulating film 13 is formed of a lower layer 13a and an upper layer 13b being laminated. The etching rate of the lower layer 13a is smaller (later) than that of the upper layer 13b, that is, (etching rate of upper layer 13b)>(etching rate of lower layer 13a). Further, the storage capacitance hole 18 is formed through the upper layer 13b but does not cut into the lower layer 13a, so the lower layer 13a forms the capacitance insulating film 19 as it is. For example, the thickness of the lower layer 13a is 100 nm, and the thickness of the upper layer 13b is 300 nm. The configurations of the present embodiment other than those described above are same as those of the first embodiment.

The composition of the lower layer 13a and the upper layer 13b may be selected appropriately corresponding to the etching conditions when forming the storage capacitance hole 18. For example, the lower layer 13a and the upper layer 13b may be formed of the same material, and the etching rates are caused to be different by adjusting the deposition conditions. In the case of forming the lower layer 13a and the upper layer 13b of SiO films deposited by the PCDV (Plasma Chemical Vapor Deposition) method, the etching rates of the films formed can be controlled by changing flow ratio of silane (SiH₄) gas or nitrous oxide (N₂O) gas in the PCDV step or by changing the deposition temperature. Further, in the case of forming the lower layer 13a and the upper layer 13b of SiN, the etching rates of the films formed can be controlled by changing the flow ratio of SiH₄ gas, ammonia (NH₃) gas, nitrogen (N₂) gas or the like in the PCVD step, or by changing the deposition temperature. In particular, the etching rate of an SiN film can be changed more dynamically than that of an SiO film.

On the other hand, the lower layer 13a and the upper layer 13b may be formed of different materials. For example, the lower layer 13a may be formed of an SiN film having smaller etching rate, and the upper layer 13b may be formed of an SiO film having larger (faster) etching rate. Alternatively, the lower layer 13a may me formed of an SiO film having smaller etching rate, and the upper layer 13b may be formed of an SiN film having larger etching rate. However, when an SiN film is used as the lower layer 13a, that is, the capacitance insulating film 19, the relative dielectric constant of the SiN film is about 1.5 times as large as the relative dielectric constant of an SiO film, so it is possible to obtain larger storage capacitance comparing with the case of using an SiO film as the capacitance insulating film 19. Therefore, since an SiN film has higher moisture stopping power than an SiO film, when the interlayer insulating film 13 is formed as a double-layered film including an SiN film, the humidity resistance reliability improves comparing with a case of forming the interlayer insulating film 13 by only using an SiO film.

Here, the ratio between the etching rates of the upper layer 13b and the lower layer 13a is preferably 2 or more. That is, assuming that the etching rate of the upper layer 13b is Rt, and the etching rate of the lower layer 13a is Rb, it is preferable that (Rt/Rb)≧2. Further, if the ratio is 4 or more, the uniformity of the capacity value of the storage capacitance C in a face of the glass substrate 2 can be improved, so it is more preferable.

In the present embodiment, when forming the storage capacitance hole 18 by etching, the lower layer 13a having a relatively small etching rate works as an etching stopper film, whereby the control property of wet etching when forming the storage capacitance insulating film 19, that is, control property of the etching amount, is improved. As a result, the uniformity of the storage capacitance C in a face of the glass substrate 2 can be improved, comparing with the first embodiment described above. The operations and effects of the present embodiment other than those described above are same as those of the first embodiment.

Note that in the present embodiment, the capacitance insulating film 19 may be a two-layered film consisting of the lower layer 13a and the upper layer 13b while not etching the upper layer 13b when forming the storage capacitance hole 18. However, it is preferable to remove the upper layer 13b by etching since it is possible to increase the capacity value of the storage capacitance.

### Third Embodiment

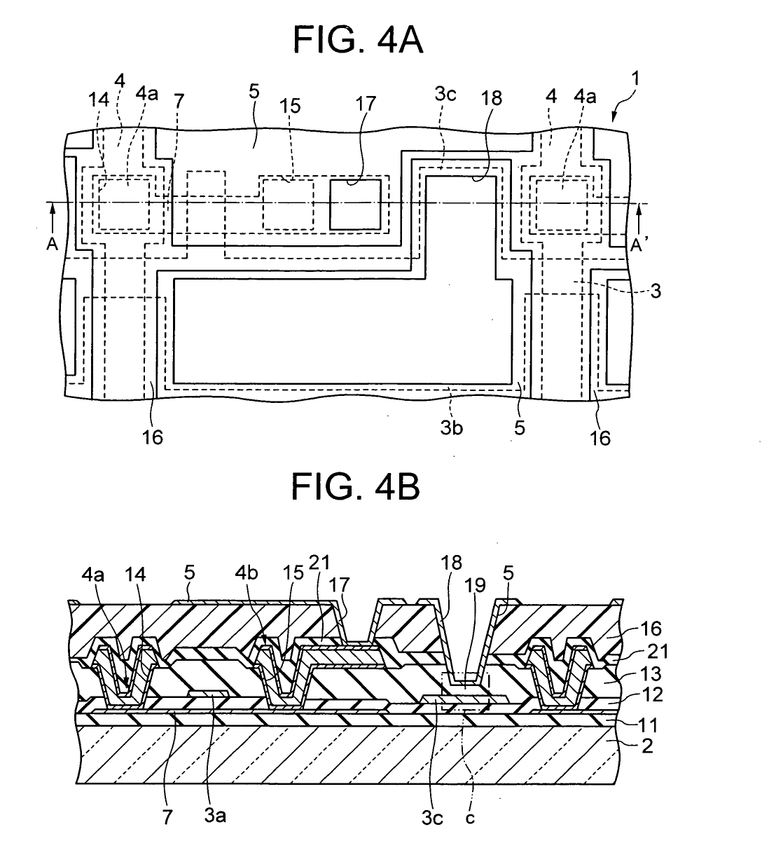

Next, a third embodiment of the present invention will be explained. FIG. 4A is a partially enlarged plan view showing a pixel circuit substrate of a liquid crystal display device according to the present embodiment, and FIG. 4B is a cross-sectional view taken along the line A-A′ in FIG. 4A. The area shown in FIG. 4A corresponds to the area 100 in FIG. 1 of the first embodiment.

As shown in FIG. 4A, the planar structure of the liquid crystal display device according to the present embodiment is same as that shown in FIG. 2A. As shown in FIG. 4B, the present embodiment is different from the first embodiment in that a protective insulating film 21 is formed between the interlayer insulating film 13, the drain line 4, the drain electrode 4a and the source electrode 4b and the planar film 16. For example, in the case where the interlayer insulating film 13 is an SiO film having a thickness of 400 nm, an SiN film having a thickness of 100 nm for example is provided as a protective insulating film 21. Further, in the case where the interlayer insulating film 13 is an SiN film having a thickness of 400 nm, an SiO film having a thickness of 200 nm for example is provided as the protective insulating film 21. The configurations of the present embodiment other than those described above are same as those of the first embodiment.

In the present embodiment, all of the gate line 3, the gate electrode 3a and the lower electrodes 3b and 3c, consisting of metallic films, and the drain line 4, the drain electrode 4a and the source electrode 4b are covered with an inorganic film (protective insulating film 21) having high corrosion resistance, so it is possible to improve corrosion lifetime of the TFT 6 and outside connecting terminal part (not shown). The operations and effects of the present embodiment other than those described above are same as those of the first embodiment.

Note that the present embodiment may be combined with the second embodiment. Thereby, the effects of both embodiments can be achieved together.

### Fourth Embodiment

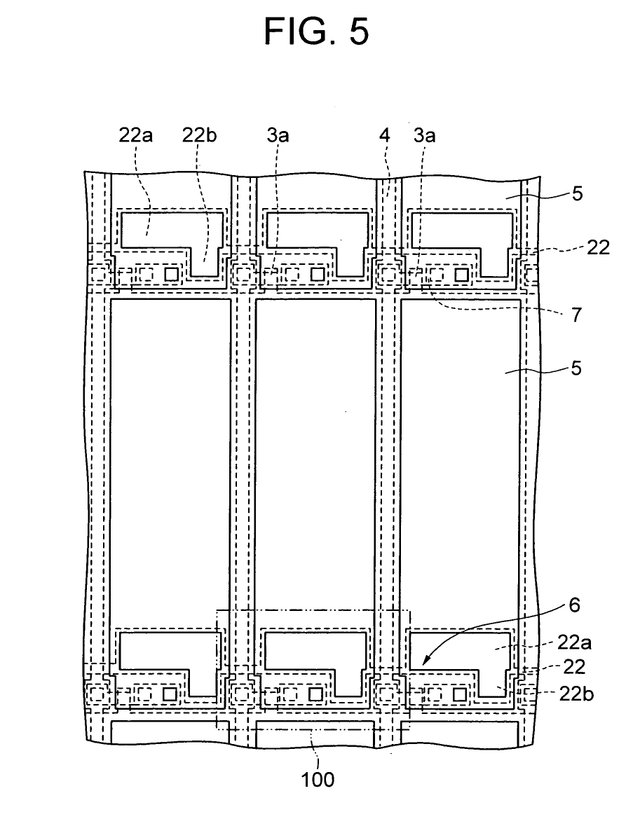

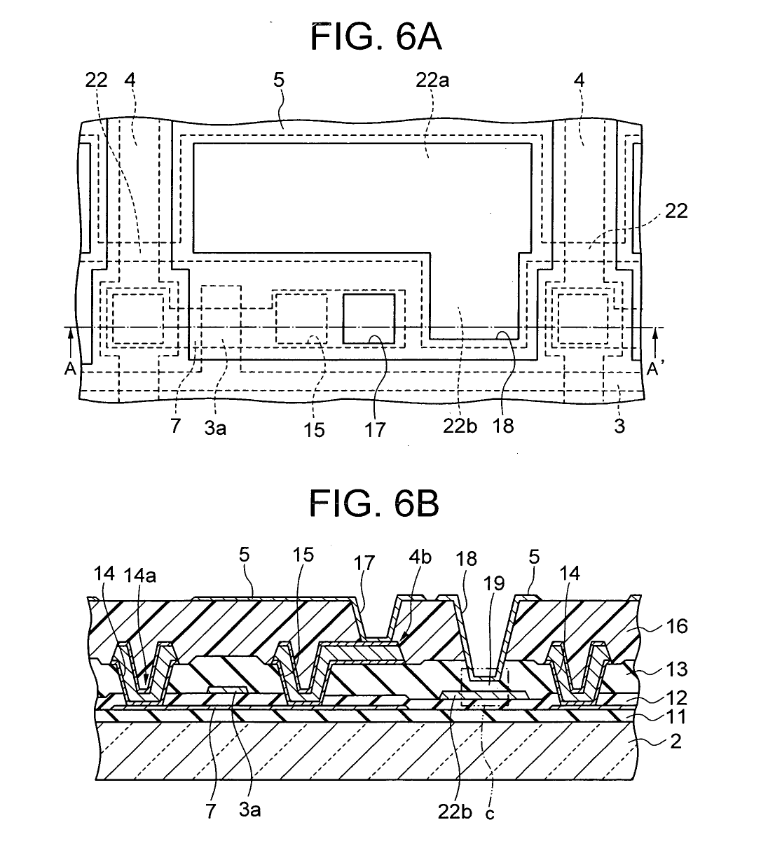

Next, a fourth embodiment of the present invention will be explained. FIG. 5 is a plan view showing a pixel circuit substrate of a liquid crystal display device according to the present embodiment, FIG. 6A is a partially enlarged plan view showing the area 100 in FIG. 5 by enlarging it, and FIG. 6B is a sectional view taken along the line A-A′ in FIG. 6A. In the present embodiment, the lower electrodes 3b and 3c (see FIG. 2A) are not provided, different from the first embodiment. That is, only the gate electrode 3a extends from the gate line 3, and a storage capacitance line 22 extending linearly in a horizontal direction and insulated from the gate line 3 is provided separate from the gate line 3. The storage capacitance line 22 is provided for each pixel row aligned in a horizontal direction, and the number of storage capacitance lines is same as the number of gate lines 3. Further, in the non-display area of the pixel circuit substrate, there is provided a storage capacitance line control circuit (not shown) for controlling potential of the storage capacitance line 22.

At each pixel, there is provided a lower electrode 22a extending from the storage capacitance line 22 to the drain line control circuit. Further, there is provided a lower electrode 22b extending from the storage capacitance line 22 in a direction apart from the drain line control circuit. The storage capacitance line 22 and the lower electrodes 22a and 22b are formed integrally of a single continuous film. Further, the storage capacitance line 22, the lower electrodes 22a and 22b, the gate line 3 and the gate electrode 3a are formed in which the same continuous film is patterned in the same step in the manufacturing process. In an area corresponding to an area immediately above the lower electrodes 22a and 22b in the interlayer insulating film 13 and the planar film 16, a storage capacitance hole 18 is formed. Further, in an area including the storage capacitance hole 18, a pixel electrode 5 of this pixel is provided. The configurations of the present embodiment other than those described above are same as those of the first embodiment.

Next, operation of the liquid crystal display device according to the present embodiment configured as described above will be explained. In the present embodiment, storage capacitance C is formed between the lower electrodes 22a and 22b and the pixel electrode 5 disposed on an area immediately above thereof. That is, the storage capacitance C is formed between the lower electrodes 22a and 22b of the n^{th} pixel from the drain line control circuit side and the pixel electrode 5 of the same n^{th} pixel.

Next, effects of the present embodiment will be explained. In the present embodiment, it is possible to apply any potential irrespective of the potential of the gate electrode 3a to the lower electrodes 22a and 22b of the storage capacitance C by the storage capacitance line control circuit and the storage capacitance line 22. In other words, potential of the lower electrodes can be controlled independently. Thereby, freedom in a driving method of the liquid crystal display device is improved, and higher display quality can be achieved.

Note that the present embodiment may be combined with the second embodiment and the third embodiment. Thereby, it is possible to achieve effects of the second to fourth embodiments together.

### Fifth Embodiment

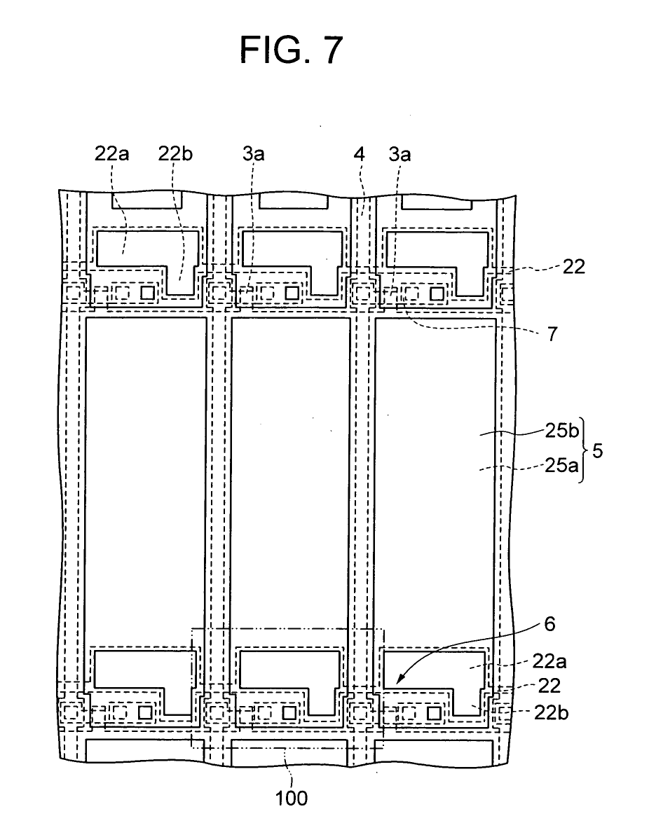

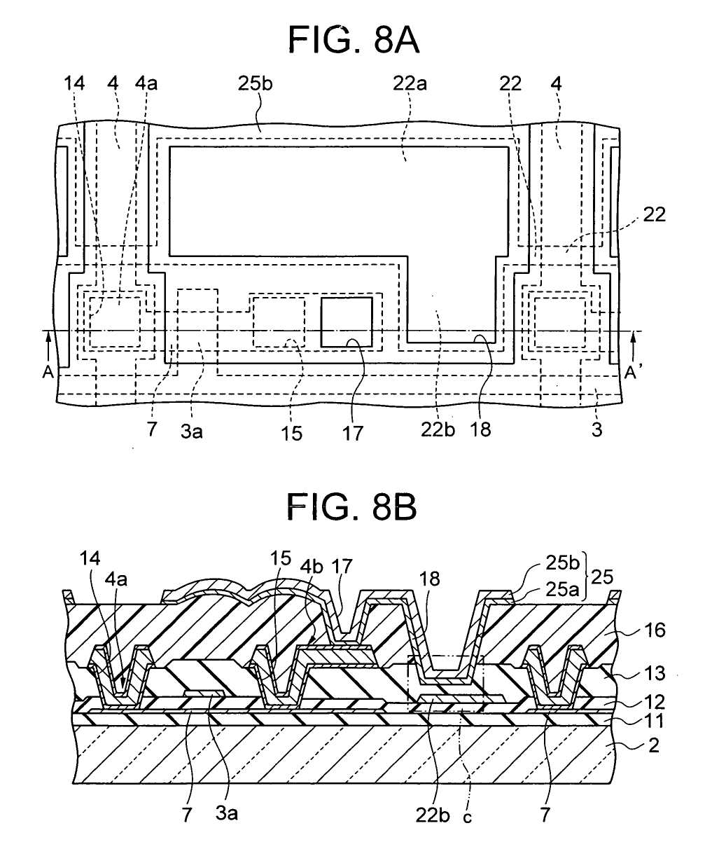

Next, a fifth embodiment of the present invention will be explained. FIG. 7 is a plan view showing a pixel circuit substrate of a liquid crystal display device according to the present embodiment, FIG. 8A is a partially enlarged plan view showing the area 100 in FIG. 7 by enlarging it, and FIG. 8B is a sectional view taken along the line A-A′ in FIG. 8A. As shown in FIGS. 7, 8A and 8B, the present embodiment is different from the fourth embodiment in that the transparent pixel electrode 5 (see FIG. 2B) is not provided on the planar film 16 and a pixel electrode 25 of a reflection type is provided. The pixel electrode 25 is so configured that the lower layer 25 a which is an Mo film having a thickness of 50nm for example and the upper layer 25b which is an Al film having a thickness of 100 nm for example are laminated. Further, on the top face of a part corresponding to an area immediately below the pixel electrode 25 in the planar film 16, irregularities are formed. The configurations of the present embodiment other than those described above are same as those of the fourth embodiment.

Next, operation of the liquid crystal display device according to the present embodiment configured as described above will be explained. In the present embodiment, the upper layer 25b of the pixel electrode 25 is formed of an Al film, whereby visible light made incident from the outside via a counter substrate can be reflected at high reflection rate. At this time, since irregularities are formed on the top face of a part corresponding to an area immediately below the pixel electrode 25 in the planar film 16, light can be reflected diffusely, whereby it is possible to prevent outer light from coming into the display image. The operations of the present embodiment other than those described above are same as those of the first embodiment.

In the present embodiment, a reflection-type liquid crystal display device can be realized. Note that the present embodiment can be combined with any embodiment among the first to fourth embodiments described above. Thereby, the first to fourth embodiments described above can be applied to a reflection-type liquid crystal display device. Further, since the lower layer 25a consisting of an Mo film is provided under the upper layer 25b consisting of an Al film, it is possible to suppress battery corrosion of the upper layer 25b. Effects of the present embodiment other than those described above are same as those of the fourth embodiment.

Although the present embodiment shows an example in which the upper layer 25b of the pixel electrode 25 is formed of an Al film, the present invention is not limited to this configuration, and the layer may be formed of another material. For example, as the upper layer 25b, an Al alloy film, a silver (Ag) film and an Ag alloy film are preferable, since they have high visible light reflection rate. Further, the pixel electrode 25 may be a single layer film such as an Al film or an Ag film. In such a case, the film thickness is preferably not less than 100 nm in order to obtain sufficient visible light reflection rate.

### Sixth Embodiment

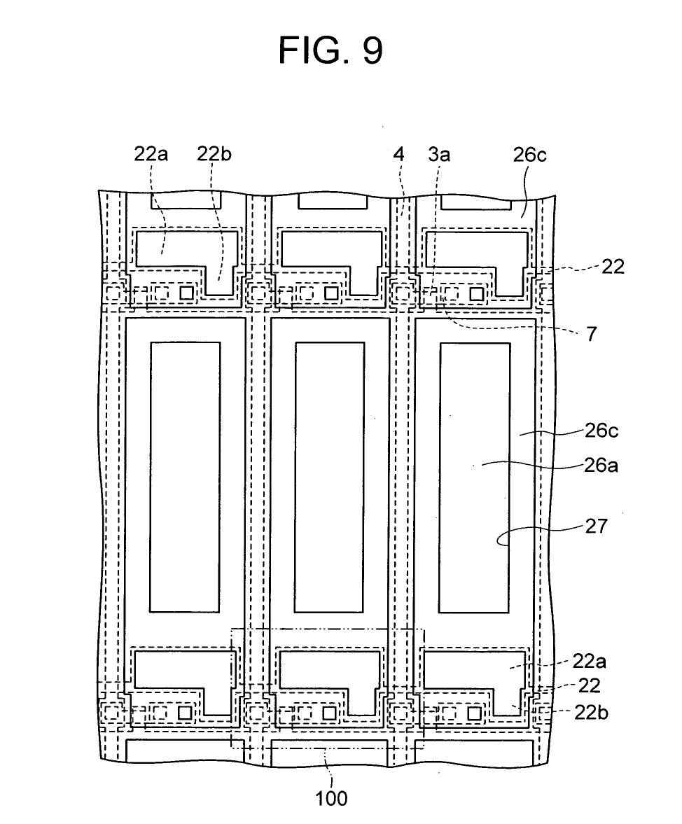

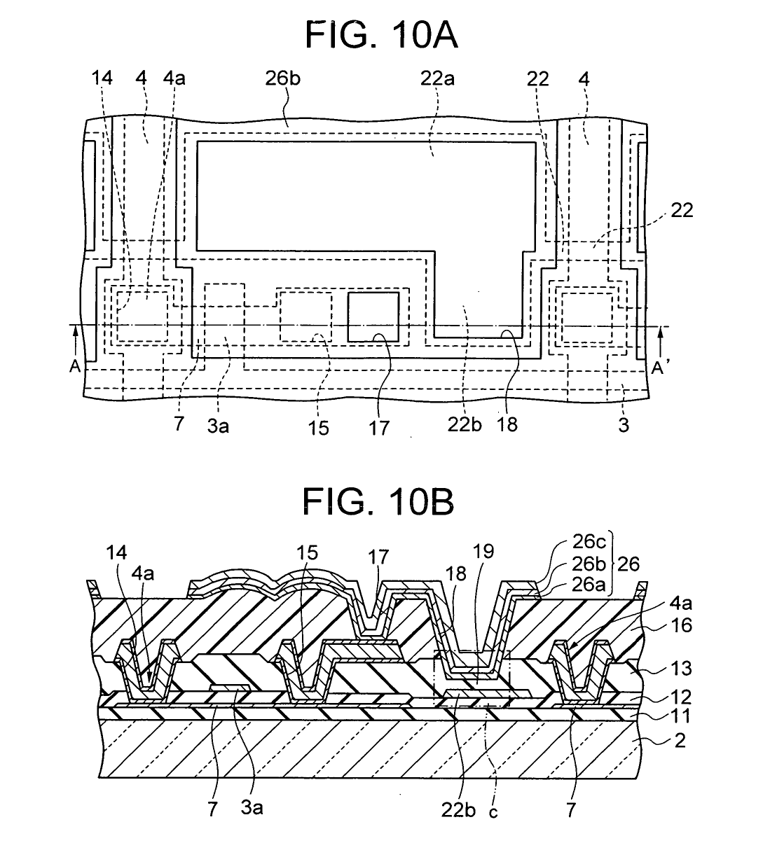

Next, a sixth embodiment of the present invention will be explained. FIG. 9 is a plan view showing a pixel circuit substrate of a liquid crystal display device according to the present embodiment, FIG. 10A is a partially enlarged plan view showing the area 100 in FIG. 9 by enlarging it, and Fig. 10B is a sectional view taken along the line A-A′ shown in FIG. 10A. As shown in FIGS. 9, 10A and 10B, the present embodiment is different from the fifth embodiment in that a pixel electrode is formed of a transparent conductive layer and a conductive layer which is laminated on a part of the transparent conductive layer and reflects a visible light, and a transparent-type area and a reflection type area are mixed in a pixel electrode. In other words, in the liquid crystal display device according to the present embodiment, a translucent-type pixel electrode 26 is provided instead of a reflection-type pixel electrode 25 (see FIG. 8B) of the fifth embodiment.

The pixel electrode 26 is so configured that a lower layer 26a consisting of an ITO film having a thickness of 100 nm for example, an intermediate layer 26b consisting of an Mo film having a thickness of 50 nm for example, and an upper layer 26c consisting of an Al film having a thickness of 100 nm for example are laminated in this order from the glass substrate 2 side. In a rectangle area 27 positioned at the center of each pixel, the intermediate layer 26b and the upper layer 26c are not provided, so only the lower layer 26a consisting of ITO is provided. On the other hand, in the area other than the rectangle area 27, the lower layer 26a, the intermediate layer 26b and the upper layer 26c are laminated so as to configure the pixel electrode 26. Further, in the rectangle area 27, irregularities are not formed on the top face of the planar film 16 so it is flat. In contrast, the area excluding the rectangle area 27 in an area immediately below the pixel electrode 26, irregularities are formed on the top face of the planar film 16. The configurations of the present embodiment other than those described above are same as those of the fifth embodiment.

Next, operation of the liquid crystal display device according to the present embodiment configured as described above will be explained. In the present embodiment, in the rectangle area 27 in the area on which the pixel electrode 26 is provided, the pixel electrode 26 is formed solely of the lower layer 26a consisting of ITO. Therefore, light made incident from the glass substrate 2 side can be transmitted to the counter substrate side. That is, it forms a transmission region. Further, in an area excluding the rectangle area 27 of the area on which the pixel electrode 26 is formed, the upper layer 25c consisting of an Al film is formed, whereby outer light made incident from the counter substrate side can be reflected at high reflection rate. That is, it forms a reflection region. At this time, since irregularities are formed on the top face of a part corresponding to an area immediately below the upper layer 26c of the planar film 16, light can be reflected diffusely, whereby it is possible to prevent outer light from coming into a display image. The operations of the present embodiment other than those described above are same as those of the fifth embodiment.

In the present embodiment, a translucent-type liquid crystal display device can be realized. Note that the present embodiment can be combined with any embodiment among the first to fourth embodiments. Thereby, the first to fourth embodiments can be applied to a liquid crystal display device of a translucent-type. The effects other than those described above of the present embodiment are same as those of the fifth embodiment.

In the present embodiment, the thickness of the liquid crystal layer (not shown) in the rectangle area 27, that is, a cell gap, may be set twice as large as the thickness of the liquid crystal layer in an area excluding the rectangle area 27. Thereby, the optical path length of the back surface transmitted light in the liquid crystal layer and the optical path length of the front surface reflected light in the liquid crystal layer can be made equal to each other. Note that back surface transmitted light means light emitted from a backlight module for example and penetrating the glass substrate 2 and the lower layer 26a positioned in the rectangle area 27 and then penetrating the liquid crystal layer, and front surface reflected light means light made incident from the counter substrate side, and after penetrating the liquid crystal layer, reflected by the upper layer 26c of the pixel electrode 26 and again penetrating the liquid crystal layer. By aligning optical path lengths of the back surface transmitted light and the front surface reflected light, it is possible to further improve display quality.

### Seventh Embodiment

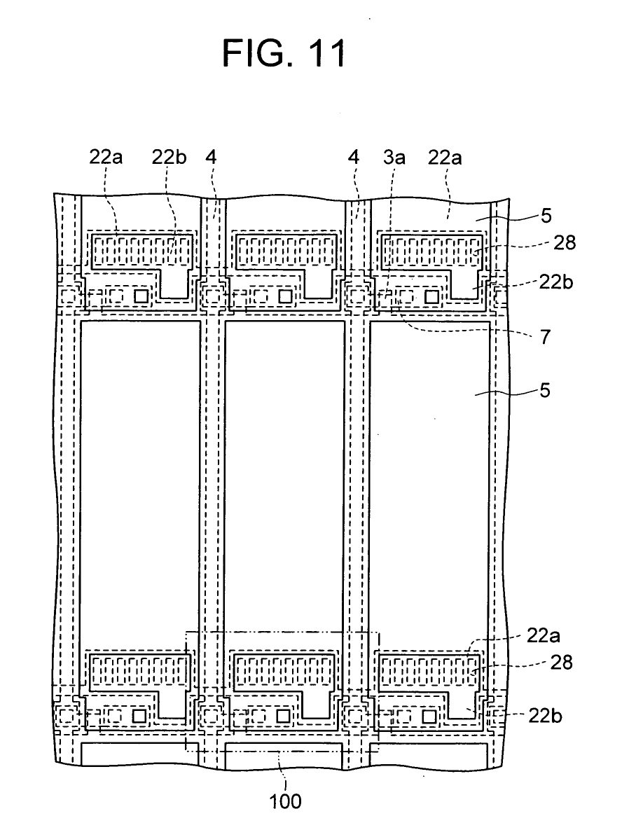

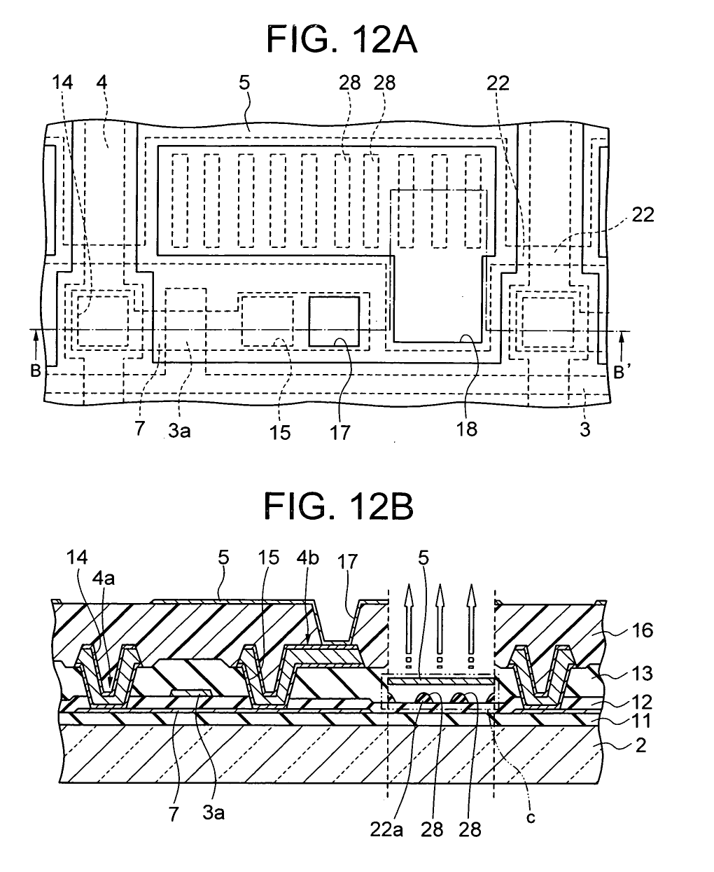

Next, a seventh embodiment of the present invention will be explained. FIG. 11 is a plan view showing a pixel circuit substrate of a liquid crystal display device according to the present embodiment, FIG. 12A is a partially enlarged plan view showing the area 100 in FIG. 11 by enlarging it, and FIG. 12B is a cross-sectional view taken along the line B-B′ in FIG. 12A. As shown in FIGS. 11, 12A and 12B, the present embodiment is different from the fourth embodiment in that apertures 28 are formed in the lower electrode 22a so the lower electrode 22a is in a meshed state. The shape of the aperture 28 is rectangle, and the apertures 28 are aligned in a line in a horizontal direction. The configurations of the present embodiment other than those described above are same as those of the fourth embodiment.

In the present embodiment, capacitance is formed between the pixel electrode 5 disposed inside the storage capacitance hole 18 due to leakage electric field by the lower electrode 22a, so effective capacity value formed by the lower electrode of a unit area increases. Therefore, even though the apertures 28 are formed in the lower electrode 22a, the capacity value of the storage capacitance C will hardly decrease. On the other hand, by forming the apertures 28 in the lower electrode 22a, light penetrates the apertures 28, whereby the amount of transmitted light of the pixel circuit substrate as a whole increases. Thereby, it is possible to realize a brighter liquid crystal display device of a translucent type while keeping the capacity value of the storage capacitance C.

Further, the cross-section of the lower electrode 22a may be in a tapered shape. Since the film thickness of the lower electrode 22a is thin, the storage capacity value will not increase significantly due to an effect that the surface area of the lower electrode 22a increases even though the cross-section is in a tapered shape, but the leakage electric field effect can be increased by forming the cross-section of the lower electrode 22a in a tapered shape. The operations and effects of the present embodiment other than those described above are same as those of the fourth embodiment.

Note that the present embodiment can be combined with the first to third embodiments. Thereby, in addition to the effects of the present invention, the effects of the first to third embodiments can also be achieved.

### Eighth Embodiment

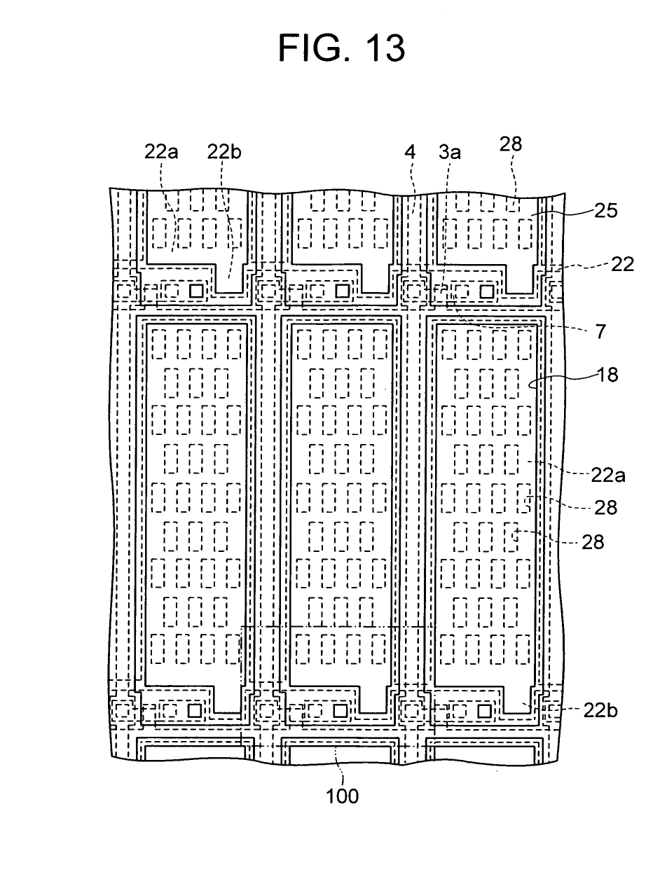

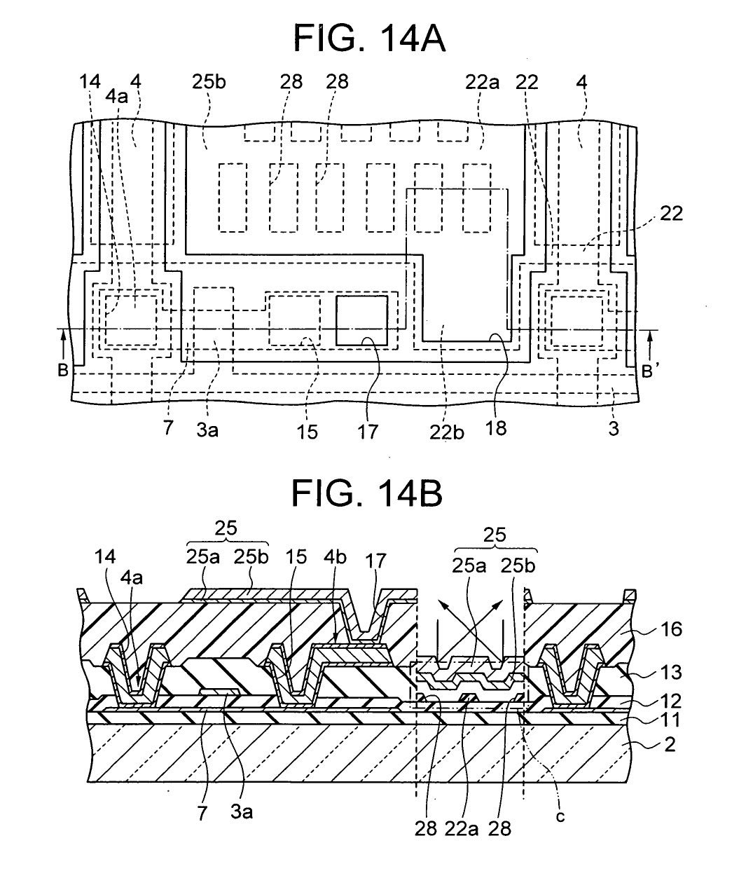

Next, an eighth embodiment of the present invention will be explained. FIG. 13 is a plan view showing a pixel circuit substrate of a liquid crystal display device according to the present embodiment, FIG. 14A is a partially enlarged plan view showing the area 100 in FIG. 13 by enlarging it, and FIG. 14B is a cross-sectional view taken along the line B-B′ in FIG. 14A. As shown in FIGS. 13, 14A and 14B, the present embodiment is different from the fifth embodiment in that the lower electrode 22a extends to the whole pixel, and the apertures 28 are formed in the lower electrode 22a, and the lower electrode 22a is in a meshed state. The shape of the aperture 28 is rectangle, and the apertures 28 are arranged in zigzags across the lower electrode 22a. On an area immediately above the lower electrode 22a of the interlayer insulating film 13 and the planar film 16, the storage capacitance hole 18 is formed. Since the lower electrode 22a extends to the whole pixel, the storage capacitance hole 18 is formed in almost whole of the pixel. The configurations of the present embodiment other than those described above are same as those of the fifth embodiment.

In the present embodiment, capacitance is formed between the pixel electrode 5 disposed inside the storage capacitance hole 18 due to leakage electric field caused by the lower electrode 22a, so the effective capacity value for each lower electrode of a unit area increases. Further, the area of the lower electrode 22a is larger compared with the fifth embodiment. Therefore, the capacity value of the storage capacitance C increases compared with the fifth embodiment. Further, at the bottom of the storage capacitance hole 18, by reflecting the shape of the lower electrode 22a in the meshed state on the shape of the planar film 16, irregularities are formed on the top face of the planar film 16. Thereby, a special step for forming irregularities on the top face of the planar film 16 is not needed, whereby the manufacturing cost decreases. Note that since the liquid crystal display device according to the present embodiment is a reflection-type liquid crystal display device, the brightness of images is not affected although the area of the lower electrode 2 increases. The operations and effects of the present embodiment other than those described above are same as those of the fifth embodiment.

Note that in the translucent-type liquid crystal display device according to the sixth embodiment, an aperture may be formed only in the lower electrode positioned in the reflection region, that is, an area excluding the rectangle area 27 in the area on which the pixel electrode 26 is provided so as to be formed in a meshed state. Thereby, a step of forming irregularities on the planar film of the reflection region can be omitted.

### Ninth Embodiment

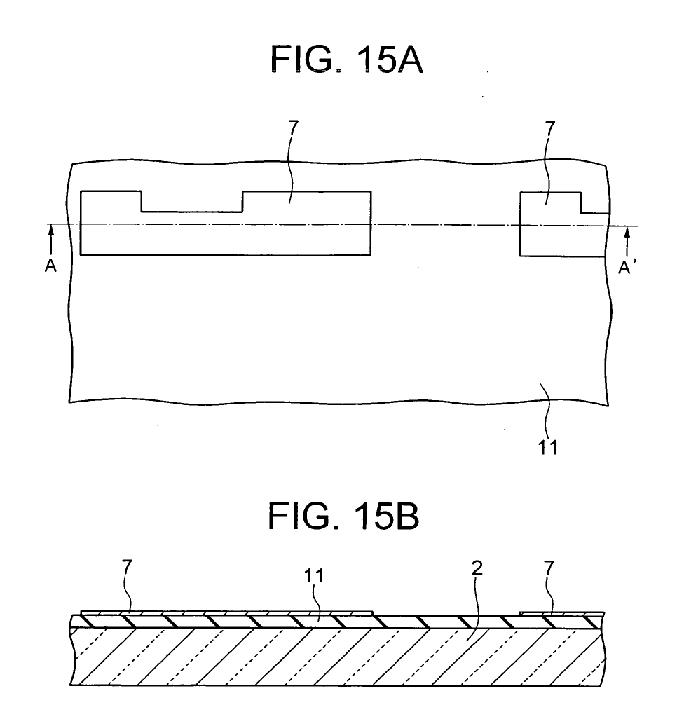

Next, a ninth embodiment of the present invention will be explained. The present embodiment is an embodiment of a manufacturing method of the liquid crystal display device according to the first embodiment. FIGS. 15 to 19 are diagrams showing the method of manufacturing the liquid crystal display device according to the present embodiment in the order of steps. FIGS. 15A, 16A, 17A, 18A and 19A are plan views, and FIGS. 15B, 16B, 17B, 18B and 19B are cross-sectional views taken along the lines A-A′ in FIGS. 15A, 16A, 17A, 18A and 19A. Hereinafter, the present embodiment will be explained with reference to FIGS. 1, 2A, 2B and 15 to 19.

First, as shown in FIGS. 15A and 15B, a silicon oxide (SiO) film is deposited so as to have a thickness of 300 nm on the glass substrate 2 by PCVD so as to form a base insulating film 11. On the base insulating film 11, an amorphous silicon (a-Si) film is deposited so as to have a thickness of 50 nm, and further an SiO film (not shown) for protection is formed thereon so as to have a thickness of 10 nm. Next, after thermally separating hydrogen inside the a-Si film, the SiO film for protection is removed by wet etching. Then, the a-Si film is melted by irradiating an excimer laser thereto, and then it is cooled and crystallized to form a polycrystalline silicon (p-Si) film. Then, the p-Si film is patterned to be in an island-shape by dry etching so as to from the active layer 7. At this time, the active layer 7 is in an almost rectangle shape extending in a horizontal direction in a plan view, and the center part in the horizontal direction is narrower than the both end parts.

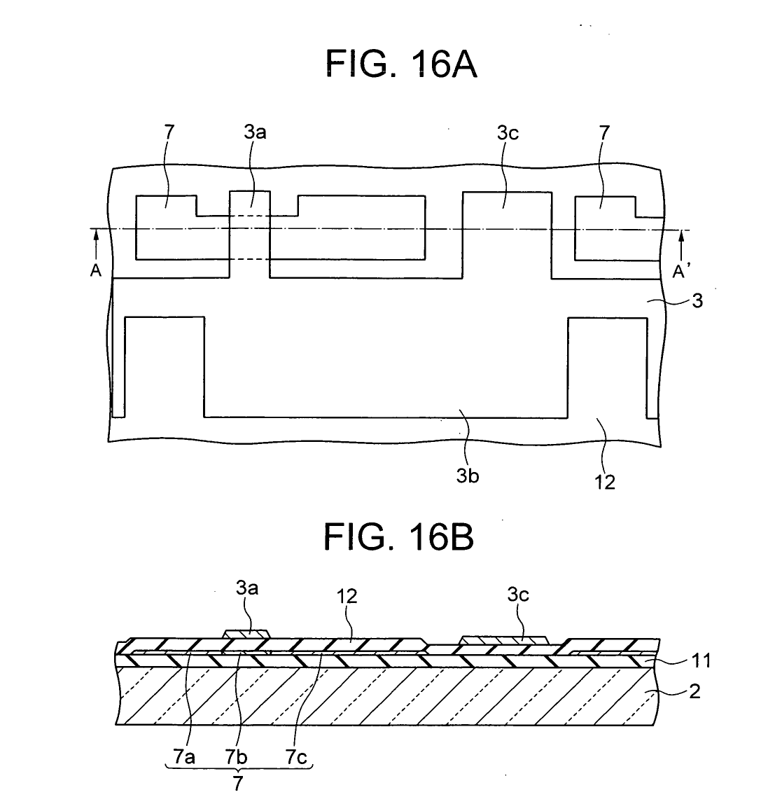

Next, as shown in FIGS. 16A and 16B, an SiO film is deposited to have a thickness of 100 nm on the base insulating film 11 so as to cover the active layer 7 by PCVD to thereby form the gate insulating film 12. Next, a molybdenum (Mo) film is deposited to have a thickness of 300 nm by sputtering, and then the Mo film is patterned by dry etching to thereby form the gate line 3 extending in a horizontal direction, the gate electrode 3a extending from the gate line 3 to an area immediately above the center part of the active layer 7, and the lower electrodes 3b and 3c extending from the gate line 3 in a vertical direction.

Next, by using the gate electrode 3a as a mask, ion doping is performed by using phosphine (PH₃) plasma to the active layer 7 so as to introduce phosphor ion into the active layer 7 under the conditions that the accelerating voltage is 70 kV and the dose amount is 4^{*}1015/cm² to thereby form N-type concentrated impurity regions at both end parts of the active layer 7. Thereby, the drain region 7a is formed at one end and the source region 7b is formed at the other end of the active layer 7. Further, a region, where the phosphor ion is not introduced, between the drain region 7a and the source region 7b of the active layer 7 becomes the channel region 7c. Note that a resist film may be formed on the gate electrode 3a, and ion doping may be performed by using the gate electrode 3a and the resist film as a mask.

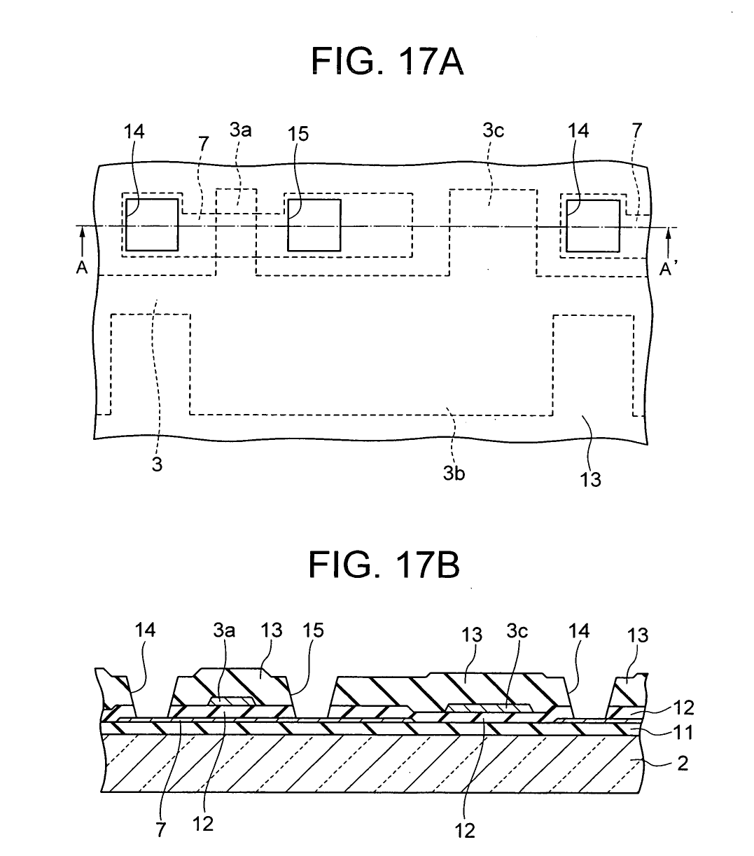

Next, as shown in FIGS. 17A and 17B, an SiO film is deposited to have a thickness of 400 nm on the gate insulating film 12 by PCVD so as to cover the gate line 3, the gate electrode 3a and the lower electrodes 3b and 3c to thereby form the interlayer insulating film 13. Note that the interlayer insulating film 13 may be formed of an SiN film or an SINO film. In such a case, it is possible to improve humidity resistance reliability, and to increase the capacity value of the storage capacitance finally formed.

Next, rapid thermal anneal (RTA) is performed so as to activate the impurity introduced in the active layer 7 to thereby cause the drain region 7a and the source region 7b to have lower resistance. Then, with hydrogenation processing using hydrogen (H₂) plasma, the defect density of dangling bond end or the like is reduced.

Next, dry etching is performed, followed by wet etching to thereby remove a part corresponding to a part of an area immediately above the drain region 7a and a part corresponding to a part of an area immediately above the source region 7b in the interlayer insulating film 13 and the gate insulating film 12. Thereby, the drain connecting hole 14 is formed in a part of the area immediately above the drain region 7a, and the source connecting hole 15 is formed in a part of the area immediately above the source region 7b.

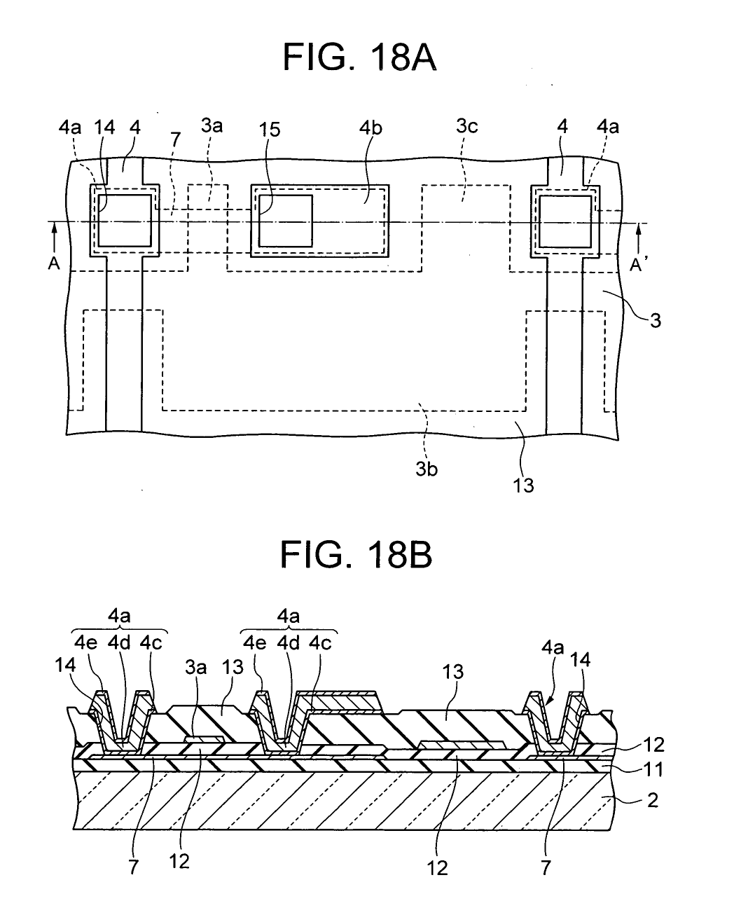

Next, as shown in FIGS. 18A and 18B, an Mo film 4c is disposed to have a thickness of 50 nm by sputtering, an aluminum (Al) film 4d is deposited to have a thickness of 300 nm, and an Mo film 4e is deposited to have a thickness of 100 nm. Then, the Mo film 4e, the Al film 4d and the Mo film 4c are patterned by wet etching so as to form the drain line 4, the drain electrode 4a and the source electrode 4b. At this time, one drain line 4 is provided for each pixel row aligned in a vertical direction, extending linearly in a vertical direction through the drain connecting hole 14. Further, the drain electrode 4a is a part corresponding to the drain connecting hole 14 in the drain line 4, which is connected with the drain region 7a of the active layer 7 at the bottom of the drain connecting hole 14. Further, the source electrode 4b is formed in an area including an area immediately above the source connecting hole 15, and is connected with the source region 7b of the active layer 7 at the bottom of the source connecting hole 15.

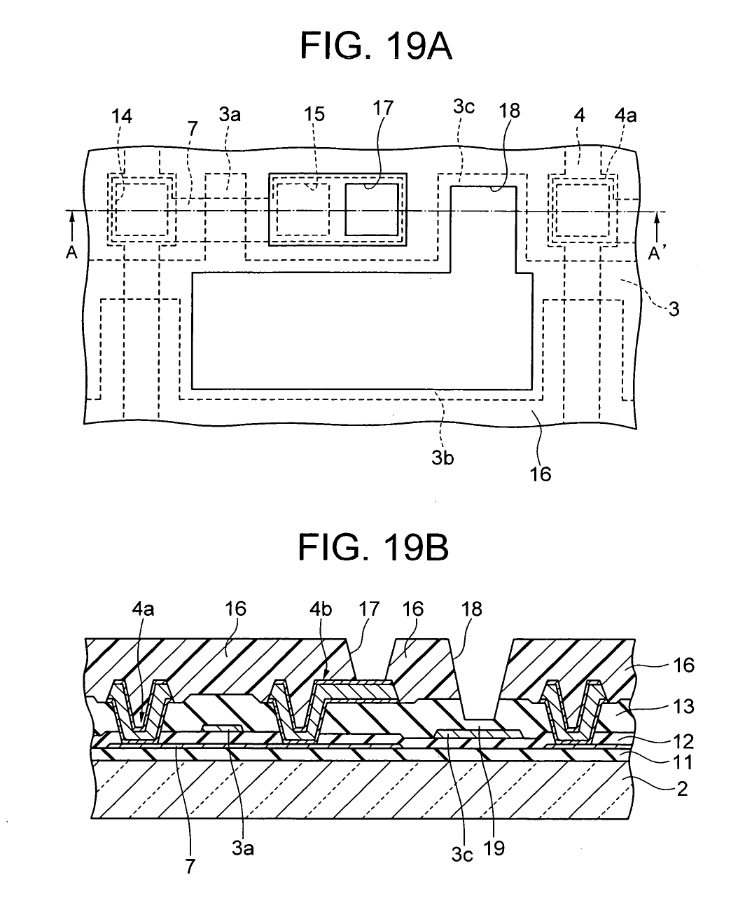

Next, as shown in FIGS. 19A and 19B, a photosensitive organic film is spin-coated onto the interlayer insulating film 13 so as to form the planar film 16 having a thickness of about 2 to 3 μm for example. At this time, the top face of the planar film 16 does not reflect the shape of the lower components lower so it is flat. Next, the planar film 16 is patterned through photolithography and removed selectively, and the pixel electrode connecting hole 17 reaching the source electrode 4b is formed in an area immediately above the source electrode 4b, and the storage capacitance hole 18 reaching the interlayer insulating film 13 is formed in an area immediately above the lower electrodes 3b and 3c. Then, through wet etching using the planar film 16 as a mask, the interlayer insulating film 13 is etched down to the depth of 300 nm at the bottom of the storage capacitance hole 18 so as to make the storage capacitance hole 18 deeper. The interlayer insulating film 13 having the remaining thickness of 100 nm at the bottom of the storage capacitance hole 18 becomes the capacitance insulating film 19 of the storage capacitance to be formed in the following step.

Note that the interlayer insulating film 13 may be used as the capacitance insulating film 19 as it is without reducing the thickness thereof. However, it is preferable to reduce the thickness of the interlayer insulating film 13 since the capacity value of the storage capacitance can be increased. Further, when forming the capacitance insulating film 19, the etching rate of the interlayer insulating film 13 is set to, for example, 6 nm/sec or less by adjusting deposition conditions or wet etching conditions of the interlayer insulating film 13, that is, concentration of hydrofluoric acid (HF) or ammonium fluoride (NH₄F) or treatment temperature while taking into account the productivity and control properties of the etching amount. However, when the etching rate becomes less than 0.2 nm/sec, the productivity drops even in batch processing, or deterioration, cracks and the like are caused in the planar film 16. Therefore, the etching rate is preferably not less than 0.2 nm/sec. Further, when the HF concentration is set to more than 10 mass %, breakage is caused when the planer film 16 is etched not only in the planar film 16 but also in the Mo film 4e, so the HF concentration is preferably not more than 10 mass %. However, from the viewpoint of productivity, HF concentration is preferably not less than 0.1 mass %.

Next, as shown in FIGS. 2A and 2B, an ITO film is deposited to have a thickness of 100 nm by sputtering. Next, the ITO film is patterned by wet etching so as to form the transparent pixel electrode 5. The pixel electrode 5 is formed in an area including the storage capacitance hole 18 of a pixel adjacent the drain line control circuit side viewed from the pixel electrode connecting hole 17 of a pixel and this pixel. Thereby, the pixel electrode 5 is provided on the side face and the bottom face of the pixel electrode connecting hole 17, and is connected with the source electrode 4b at the bottom face of the pixel electrode connecting hole 17. Further, the pixel electrode 5 is not formed in an area immediately above the lower electrodes 3b and 3c of a pixel to which the pixel electrode 5 belongs, that is, the lower electrodes 3b and 3c connected with the pixel electrode 5 via the TFT 6. Instead, the pixel electrode 5 is formed in an area immediately above the lower electrodes 3b and 3c of a pixel adjacent the drain line control circuit side viewed from this pixel. On the other hand, in an area immediately above the lower electrodes 3b and 3c of a pixel to which the pixel electrode 5 belongs, there is formed a pixel electrode 5 of a pixel adjacent a side receding from the drain line control circuit (lower side in the longitudinal direction of the figure) viewed from this pixel.

Thereby, storage capacitance C is formed between the lower electrodes 3b and 3c provided to the n^{th} pixel from the drain line control circuit side and the pixel electrode 5 disposed on the bottom face of the storage capacitance hole 18 formed in an area immediately above the lower electrodes 3b and 3c, that is, the pixel electrode 5 provided to the (n+1)^{th} pixel. The pixel electrode 5 provided to the (n+1)^{th} pixel serves as the upper electrode of the storage capacitance C, and the part in which the thickness is reduced, positioned at the bottom of the storage capacitance hole 18 in the interlayer insulating film 13, serves as the capacitance insulating film 19 of the storage capacitance C. Thereby, the storage capacitance is added to the pixel electrode 5. In this way, the pixel circuit substrate 1 in the first embodiment is produced. Then, the pixel circuit substrate 1 and the counter substrate (not shown) are arranged in parallel with a distance to each other, and liquid crystal is filled between the substrates so as to form a liquid crystal layer, whereby the liquid crystal display device according to the first embodiment is manufactured.

Next, effects of the present embodiment will be explained. In the present embodiment, the lower electrodes 3b and 3c of the storage capacitance C are formed in the same step by patterning the same film as the gate line 3 and the gate electrode 3a. Further, the capacitance insulating film 19 of the storage capacitance C is formed of a part of the interlayer insulating film 13. Further, the upper electrode of the storage capacitance C is formed of a part of the pixel electrode 5. Therefore, a specific step for forming the storage capacitance C is not required, and the manufacturing cost of the liquid crystal display device will not increase with the formation of the storage capacitance C. The effects of the liquid crystal display device manufactured by means of the present embodiment are same as those of the first embodiment.

Note that although the present embodiment has been described with an example of producing an N-type TFT by introducing N-type impurity into the drain region 7a and the source region 7b in the active layer 7, a P-type TFT may be produced by introducing P-type impurity. In such a case, through ion doping using die borane (B2H6) plasma, boron ion is introduced into the active layer 7 under the conditions that the accelerating voltage is 80 kV and the dose amount is 2^{*}1015/cm².

Further, in the present embodiment, ion doping for controlling threshold voltage may be performed before heat-separating hydrogen in the a-Si film.

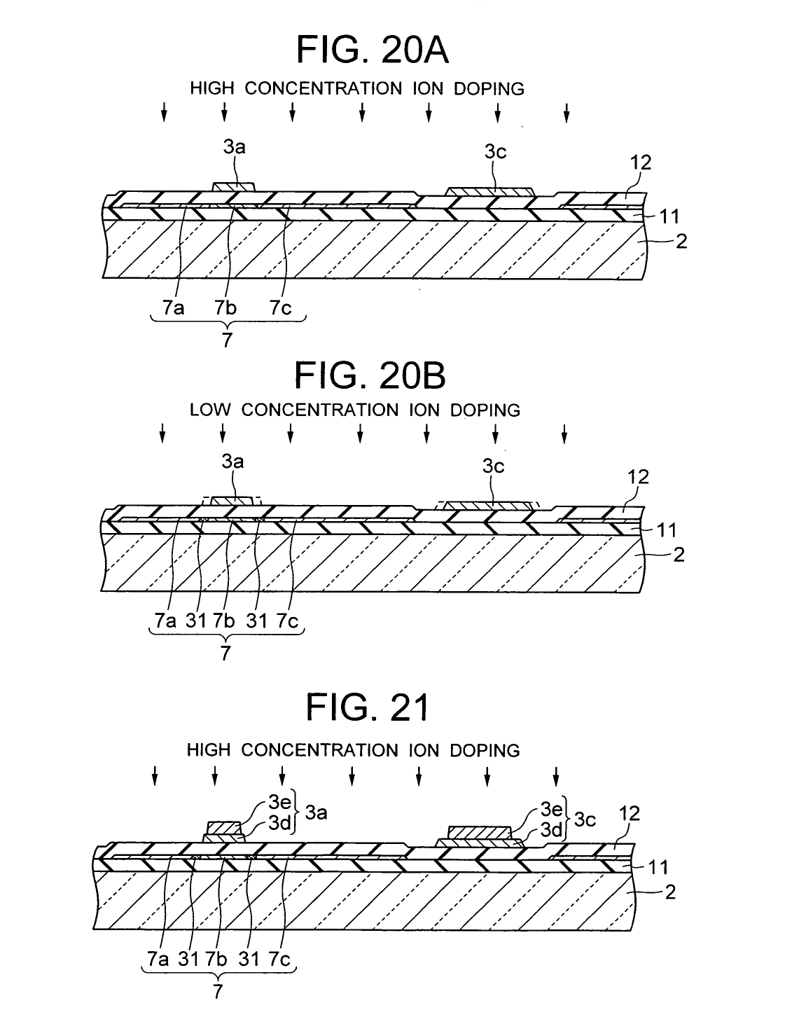

Next, a first modification of the present embodiment will be explained. In the present modification, a low concentration impurity region (LDD region) is formed in the active layer 7. FIGS. 20A and 20B are cross-sectional views showing a method of forming an LDD region in the present modification in the order. Note that FIGS. 20A and 20B show the same cross-section as that of FIG. 16B.

As shown in FIG. 20A, ion doping is performed by using the gate electrode 3a as a mask, and the drain region 7a and the source region 7b which are high concentration impurity regions are formed in the active layer 7. Next, as shown in FIG. 20B, the width of the gate electrode 3a is reduced by dry etching and wet etching, and ion doping is performed again by using the reduced gate electrode 3a as a mask, whereby LDD regions 31 are formed between the drain region 7a and the channel region 7c and between the source region 7b and the channel region 7c. Thereby, it is possible to form LDD regions without increasing the number of photomasks. The configurations, operations and effects of the present modification other than those described above are same as those of the ninth embodiment.

Next, a second modification of the present embodiment will be explained. Also in the present modification, LDD regions are formed in the active layer 7 same as the first modification. FIG. 21 is a cross-sectional view showing a method of forming an LDD region in the present modification. Note that FIG. 21 shows the same cross-section as that of FIG. 16B. As shown in FIG. 21, in the present modification, the gate electrode 3a is formed in stepwise. That is, the gate electrode 3a is in a double-layered structure consisting of the lower layer 3d and the upper layer 3e formed on a part of the lower layer 3d. Then, ion doping is performed by using the stepwise gate electrode 3a as a mask. Thereby, in an area immediately below the lower layer 3d but excluding an area immediately below the upper layer 3e in the active layer 7, a part of the ion is blocked with the lower layer 3d, whereby the smaller amount of ion is introduced compared with the area excluding the area immediately below the lower layer 3d. Thereby, the LDD region 31 is formed in the active layer 7. The configurations, operations and effects of the present deformation other than those described above are same as those of the ninth embodiment.

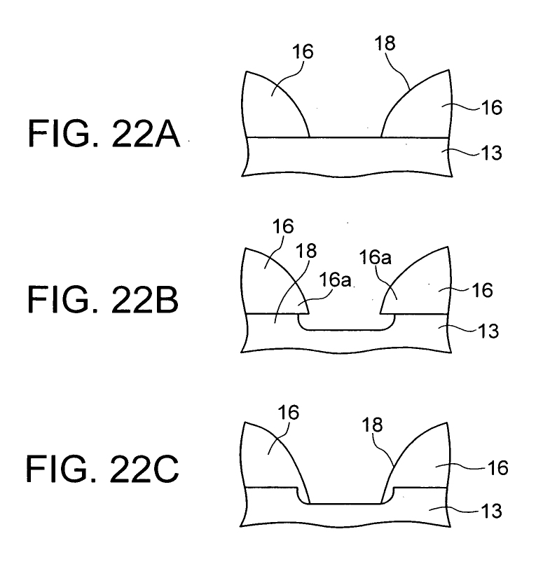

Next, a third modification of the present embodiment will be explained. FIGS. 22A and 22B are cross-sectional views showing a method of patterning a planar film in the present modification in the order of steps. As shown in FIG. 22A, in the ninth embodiment, when the planar film 16 is patterned, there may be a case where the interlayer insulating film 13 is side-etched and a protruded part 16a is formed on the side face of the storage capacitance hole 18 in the planar film 16 to be in a peaked shape as shown in FIG. 22B, depending on the film material and the wet etching conditions. In such a case, the planar film 16 is reflowed so as to improve the peaked shape as shown in FIG. 22C. The configurations, operations and effects of the present modification other than those described above are same as those of the ninth embodiment.

### Tenth Embodiment

Next, a tenth embodiment of the present invention will be explained. The present embodiment is an embodiment of a method of manufacturing the liquid crystal display device according to the second embodiment. As shown in FIGS. 3A and 3B, when the interlayer insulating film 13 is formed, the lower layer 13a having a thickness of 100 nm for example is formed first, and then the upper layer 13b having a thickness of about 300 nm for example is formed, in the present embodiment. Then, when the storage capacitance hole 18 is formed, the upper layer 13b of the planar film 16 and the interlayer insulating film 13 is removed selectively by etching so as to form the storage capacitance hole 18, and the lower layer 13a of the interlayer insulating film 13 remains at the bottom of the storage capacitance hole 18.

The composition of the lower layer 13a and the upper layer 13b is selected appropriately corresponding to the etching conditions when the storage capacitance hole 18 is formed. For example, the lower layer 13a and the upper layer 13b are formed of the same kind of material, and the etching rates are made different by adjusting deposition conditions. In the case where the lower layer 13a and the upper layer 13b are formed of SiO films deposited by PCVD method, the etching rates of the films formed are controlled by changing the flow ratio of shiran (SiH₄) gas or nitrous oxide (N₂O) gas in the PCVD process, or by changing the deposition temperature. Further, in the case where the lower layer 13a and the upper layer 13b are formed of SiN, the etching rates of the films formed are controlled by changing the flow ratio of SiH₄ gas, ammonia (NH₃) gas, nitrogen (N₂) gas or the like in the PCVD process or changing the deposition temperature. In particular, for an SiN film, etching rate can be changed dynamically than an SiO film.

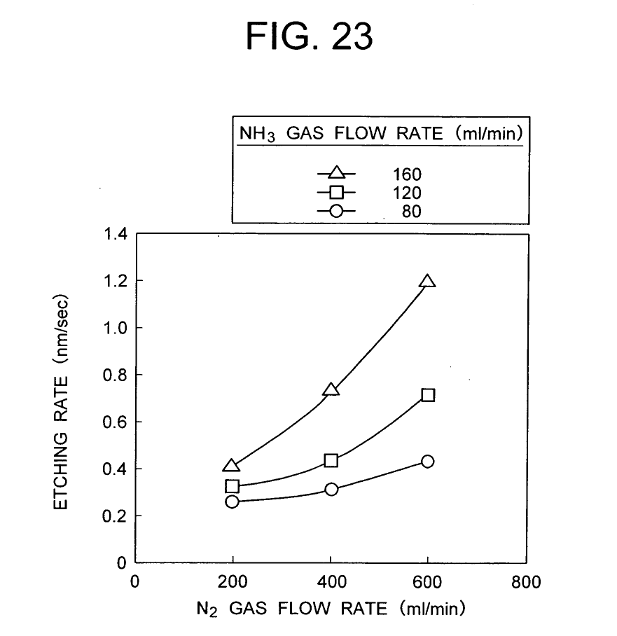

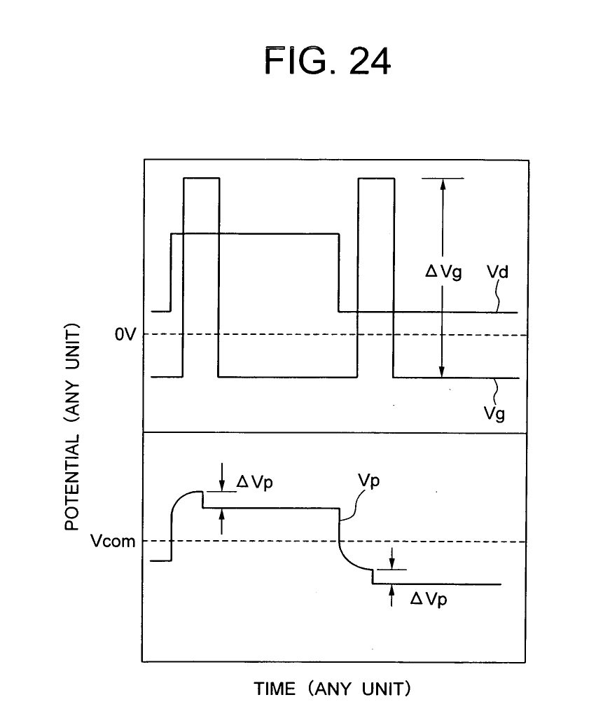

FIG. 23 is a graph showing, when an SiN film is deposited by the PCDV method, an example of influence affected on the etching rate of the SiN film after deposition by the NH₃ gas flow rate and the N₂ gas flow rage, where the horizontal axis shows flow rate of N₂ gas and the vertical axis shows etching rate. Other deposition conditions of the SiN film are as follows: SiH₄ gas flow rate is 60 ml/min (sccm), H₂ gas flow rate is 400 ml/min, substrate temperature is 350° C., and high-frequency electric density is 950 W/m². Further, the wet etching conditions are as follows: HF concentration, that is, the ratio of HF amount to the total amount of HF and NH₄F (HF/(HF+N H₄F)) is 4 mass %, and the processing temperature is room temperature. As shown in FIG. 23, the etching rate of the SiN film increases when the N₂ gas flow rate increases when deposition, and increases when the NH₃ gas flow rate increases, for example. In this way, by changing the deposition conditions of PCVD, it is possible to control the etching rate of the SiN film in a wide range.

Note that in the present embodiment, the lower layer 13a and the upper layer 13b may be formed of different materials. For example, the lower layer 13a may be formed of an SiN film having a small etching rate, and the upper layer 13b may be formed of an SiO film having a large etching rate. Alternatively, the lower layer 13a may be formed of an SiO film having a small etching rate, and the upper layer 13b may be formed of an SiN film having a large etching rate. However, if the lower layer 13a serving as the capacitance insulating film 19 later is formed of an SiN film, it is possible to obtain larger storage capacity value than the case of forming the lower layer 13 of an SiO film, since the relative dielectric constant of an SiN film is 1.5 times as large as the relative dielectric constant of an SiO film.

The ratio of the etching rate of the upper layer 13b to the etching rate of the lower layer 13a is preferably not less than 2. Further, if the ratio is not less than 4, the uniformity of the capacity value of the storage capacitance C can be improved within the face of the glass substrate 2, whereby it is more preferable.

In the present embodiment, when the storage capacitance hole 18 is formed by etching, the lower layer 13a in which the etching rate is relatively small serves as an etching stopper film, whereby the control properties of wet etching when the storage capacitance insulating film 19 is formed, that is, the control properties of the etching amount, is improved. As a result, compared with the ninth embodiment, it is possible to improve the uniformity of the storage capacitance C within the face of the glass substrate 2. The configurations, operations and effects of the present embodiment other than those described above are same as those of the ninth embodiment.

### Eleventh Embodiment

Next, an eleventh embodiment of the present invention will be explained. The present embodiment is an embodiment of a manufacturing method of the liquid crystal display device according to the third embodiment. As shown in FIGS. 4A and 4B, in the present embodiment, the interlayer insulating film 13 is formed, the drain connecting hole 14 and the source connecting hole 15 are formed in the interlayer insulating film 13, and after the drain line 4, the drain electrode 4a and the source electrode 4b are formed, the protective insulating film 21 is formed. For example, when an SiO film is deposited to have a thickness of 400 nm as the interlayer insulating film 13, an SiN film is deposited to have a thickness of 100 nm as the protective insulating film 21. When an SiN film is deposited to have a thickness of 400 nm as the interlayer insulating film 13, an SiO film is deposited to have a thickness of 200 nm as the protective insulating film 21. The configurations, operations and effects of the present embodiment other than those described above are same as those of the ninth embodiment.

### Twelfth Embodiment

Next, a twelfth embodiment of the present invention will be explained. The present embodiment is an embodiment of a method of manufacturing the liquid crystal display device according to the fourth embodiment. As shown in FIGS. 5, 6A and 6B, when the gate line 3 and the gate electrode 3a are formed, the lower electrodes 3b and 3c (see FIG. 16A) connected with the gate line 3 are not formed but the storage capacitance line 22 separated from the gate line 3 and the lower electrodes 22a and 22b connected therewith are formed, in the present embodiment. More specifically, after the gate insulating film 12 is formed, an Mo film is deposited to have a thickness of 300 nm by sputtering. Next, the Mo film is patterned by dry etching so as to form the gate line 3 extending in a horizontal direction and the gate electrode 3a extending from the gate line 3 to an area immediately above the center part of the active layer 7, and besides the gate line 3, there are formed the storage capacitance line 22 extending linearly in a horizontal direction, the lower electrode 22a extending from the storage capacitance line 22 toward the drain line control circuit, and the lower electrode 22b extending from the storage capacitance line 22 in a direction away from the drain line control circuit. The storage capacitance line 22 is formed for each pixel row aligned in the horizontal direction. Further, in a non-display area if the pixel circuit substrate, a storage capacitance line control circuit (not shown) for controlling potential of the storage capacitance line 22 is formed. The configurations, operations and effects of the present embodiment other than those described above are same as those of the ninth embodiment.

### Thirteenth Embodiment

Next, a thirteenth embodiment of the present invention will be explained. The present embodiment is as embodiment of a manufacturing method of the liquid crystal display device according to the fifth embodiment. As shown in FIGS. 7, 8A and 8B, after the planar film 16 is formed, halftone exposure is performed to an area to which a pixel electrode 25 is to be formed in the planar film 16 to thereby form irregularities on the top face of the planar film 16. Note that an area in which the pixel electrode 25 is to be formed in the planar film 16 may be patterned to be in a columnar shape to thereby form irregularities on the top face of the planar film 16 by applying photosensitive optical film. Next, after the Mo film is deposited to have a thickness of 50 nm, the Al film is deposited to have a thickness of 100 nm. Then, the Al film and the Mo film is patterned by wet etching so as to remain the Al film and the Mo film on an area where the irregularities are formed on the top face of the planar film 16, and the Al film and the Mo film form the upper layer 25b and the lower layer 25a of the pixel electrode 25, respectively. Thereby, the reflection-type pixel electrode 25 of the double-layered structure is formed. The configurations, operations and effects of the present embodiment other than those described above are same as those of the ninth embodiment.

Note that although the present embodiment shows an example of forming the upper layer 25b of the pixel element 25 of an Al film, the present invention is not limited to this. The upper layer 25b may be any film provided that the visible light reflection rate is high such as an Al alloy film, a silver (Ag) film or an Ag alloy film. Further, the pixel electrode 25 may be formed of a single layered film such as an Al film or an Ag film. In such a case, it is preferable that the film thickness be not less than 100 nm in order to obtain sufficient visible light reflection rate.

### Fourteenth Embodiment

Next, a fourteenth embodiment of the present invention will be explained. The present embodiment is an embodiment of a manufacturing method of the liquid crystal display device according to the sixth embodiment. As shown in FIGS. 9, 10A and 10B, in the present embodiment, irregularities are formed on the top face of the planar film 16 by the same method as the thirteenth embodiment. Next, after an ITO film is deposited to have a thickness of 100 nm, the ITO film is patterned to thereby form a transparent lower layer 26a of a pixel electrode 26. Next, after an Mo film is deposited to have a thickness of 50 nm, an Al film is deposited to have a thickness of 100 nm. Then the Al film and the Mo film are patterned by wet etching so as to remain the Al film and the Mo film in an area immediately above the area where the irregularities are formed in the top face of the planar film 16, whereby the Al film and the Mo film form the upper layer 26c and the intermediate layer 26b, respectively. In a rectangle area 27 positioned at the center part of the pixel, the Al film and the Mo film are removed so as to expose the transparent lower layer 26a. The configurations, operations and effects of the present embodiment other than those described above are same as those of the ninth embodiment.

### Fifteenth Embodiment

Next, a fifteenth embodiment of the present invention will be explained. The present embodiment is an embodiment of a manufacturing method of the liquid crystal display device according to the seventh embodiment. As shown in FIGS. 11, 12A and 12B, when the lower electrode 22a is formed, the apertures 28 are formed in the lower electrode 22a so as to form the lower electrode 22a in a meshed state. Note that if the interlayer insulating film 13 is formed on the lower electrode 22a, the shape of the interlayer insulating film 13 reflect the shape of the lower electrode 22a whereby irregularities are formed on the top face. However, by reducing the etching rate of the wet etching performed to the interlayer insulating film 13 when forming the storage capacitance hole 18, the top face of the interlayer insulating film 13 becomes flat by an etch-back effect. The configurations, operations and effects of the present embodiment other than those described above are same as those of the twelfth embodiment.

### Sixteenth Embodiment

Next, a sixteenth embodiment of the present invention will be explained. The present embodiment is an embodiment of a manufacturing method of the liquid crystal display device according to the eighth embodiment. As shown in FIGS. 13, 14A and 14B, when the lower electrode 22a is formed, the lower electrode 22a is formed substantially all over a pixel and a plurality of apertures 28 are formed in zigzags so as to form the lower electrode 22a to be in a meshed state. Further, when the storage capacitance hole 18 is formed, the storage capacitance hole 18 is formed in an area immediately above the lower electrode 22a, that is, almost all over a pixel. Further, when wet etching is performed to the interlayer insulating film 13 at the bottom of the storage capacitance hole 18, a large etching rate is set. Thereby, the top face of the interlayer insulating film 13 hardly becomes flat by the etch-back effect. Therefore, it is possible to remain the irregularities on the top face of the interlayer insulating film 13, different from the fifteenth embodiment. The configurations of the present embodiment other than those described above are same as those of the thirteenth embodiment.

In the present embodiment, the shape of the meshed lower electrode 22a is reflected on the shape of the planar film 16 at the bottom of the storage capacitance hole 18 whereby irregularities are formed on the top face of the planar film 16. Thereby, a special step for forming irregularities on the top face of the planar film 16 is not required, so the manufacturing cost is reduced. The operations and effects of the present embodiment other than those described above are same as those of the thirteenth embodiment.

Note that in each embodiment described above, a transparent plastic substrate may be provided instead of the glass substrate 2. Further, the base insulating film 11 may have a double-layered structure in which the lower layer consists of an SiN film or a silicon oxynitride film (SiON film) and the upper layer consists of an SiO film. Thereby, it is possible to prevent diffusion of alkali ion from the glass substrate more securely. Further, the gate insulating film 12 may be formed of an SiON film or an SiN film. Alternatively, the gate insulating film 12 may be a multilayered film in which an SiO film, an SiON film, an SiN film and the like are laminated. Further, although each embodiment described above shows an example in which control circuits such as a gate line control circuit and a drain line control circuit are provided on a glass substrate of a pixel circuit substrate, these control circuits may not be formed on the pixel circuit substrate and these control circuits may be provided outside a liquid crystal panel consisting of a pixel circuit substrate and a counter substrate. In such a case, the n^{th} gate line and the n^{th} pixel described above mean, for example, the n^{th} gate line and pixel from the side on which connecting terminals for connecting drain lines on the glass substrate with an outside drain line control circuit are disposed.

### Industrial Applicability

The present invention can be applied preferably to, for example, a liquid crystal display device of an active-matrix type.

What is claimed is:

1. A liquid crystal display device comprising:
a pixel circuit substrate;
a counter substrate; and
a liquid crystal layer disposed between the pixel circuit substrate and the counter substrate, wherein
the pixel circuit substrate includes: a substrate; a transistor provided for each pixel on the substrate; a lower electrode provided in an area outside an area immediately above an active layer of the transistor; an insulating film provided so as to cover the lower electrode; and a pixel electrode provided in an area including an area immediately above the lower electrode on the insulating film, and connected with one of a source and a drain of the transistor, and
storage capacitance is formed between the lower electrode and the pixel electrode.

2. The liquid crystal display device, as claimed in claim 1, wherein the pixel circuit substrate includes: a plurality of data lines, extending in one direction, connected with another one of the source and the drain of the transistor; and a plurality of gate lines, extending in a direction crossing the one direction, connected with a gate electrode of the transistor, and
the pixel electrode, which is provided in an area including an area immediately above the lower electrode and storage capacitance is formed between it and the lower electrode, is connected with one of the source and the drain of the transistor in which a gate line, other than the gate line connected with the lower electrode, is connected with a gate electrode thereof.

3. The liquid crystal display device, as claimed in claim 1, wherein a dented part is formed in a part corresponding to an area immediately above the lower electrode in the insulating film, and a part corresponding to an area immediately above the lower electrode in the pixel electrode is provided at a bottom of the dented part.

4. The liquid crystal display device, as claimed in claim 3, wherein the insulating film includes: an interlayer insulating film, provided so as to cover the gate electrode of the transistor, on which the data line connected with the other one of the source and the drain of the transistor is disposed; and a planar film, provided so as to cover the data line on the interlayer insulating film, on which the pixel electrode is disposed; and
the dented part is formed through the planar film down to a middle of the interlayer insulating film.

5. The liquid crystal display device, as claimed in claim 4, wherein the interlayer insulating film includes a lower layer and an upper layer formed on the lower layer, and the dented part is formed through the planar film and the upper layer but not through the lower layer.

6. The liquid crystal display device, as claimed in claim 1, wherein a plurality of apertures are formed in the lower electrode.

7. The liquid crystal display device, as claimed in claim 1, wherein the pixel electrode includes a transmission region made of a transparent conductive material and a reflection region made of a conductive material in which at least a surface thereof reflects visible light.

8. The liquid crystal display device, as claimed in claim 7, wherein a plurality of apertures are formed in a lower electrode in an area immediately below the reflection region, and irregularities reflecting a shape of the lower electrode are formed on a top face of a part of an insulating film corresponding to an area immediately below the reflection region of the pixel electrode.

9. A method of manufacturing a liquid crystal display device comprising the steps of:
producing a pixel circuit substrate;
producing a counter substrate; and
forming a liquid crystal layer between the pixel circuit substrate and the counter substrate, wherein
the step of producing the pixel circuit substrate includes the steps of: forming a semiconductor layer locally on the substrate; forming a gate insulating film so as to cover the semiconductor layer; forming a conductive film on the gate insulating film and patterning the conductive film to thereby form a gate electrode and a lower electrode; introducing impurity into the semiconductor layer so as to form an active layer, and forming a transistor including the active layer, the gate insulating film and the gate electrode; forming an insulating film so as to cover the gate electrode and the lower electrode; and forming a pixel electrode so as to be connected with one of a source and a drain of the transistor in an area including an area immediately above the lower electrode on the insulating film.

10. The method of manufacturing the liquid crystal display device, as claimed in claim 9, wherein in the step of forming the gate electrode and the lower electrode, the conductive film is patterned to thereby form a plurality of gate lines extending in one direction and to form the gate electrode and the lower electrode so as to be connected with the gate lines, and
in the step of forming the pixel electrode, the pixel electrode provided in an area including an area immediately above the lower electrode is formed to be connected with one of the source and the drain of the transistor in which a gate line, other than the gate line with which the lower electrode is connected, is connected with the gate electrode.

11. The method of manufacturing the liquid crystal display device, as claimed in claim 9, wherein the step of forming the insulating film includes the steps of: forming an interlayer insulating film so as to cover the gate electrode; and forming a planar film on the interlayer insulating film so as to cover a data line connected with another one of the source and the drain of the transistor, and
a step of forming a dented part includes the steps of: etching the planar film so as to remove it selectively; and etching the interlayer insulating film by using the planar film as a mask so as to remove the interlayer insulating film selectively.

12. The method of manufacturing the liquid crystal display device, as claimed in claim 11, wherein the step of forming the interlayer insulating film includes the steps of: forming a lower layer; and forming an upper layer on the lower layer, and
the step of etching the interlayer insulating film so as to remove it selectively is a step of etching the upper layer by using the lower layer as an etching stopper film.

13. The method of manufacturing the liquid crystal display device, as claimed in claim 9, wherein in the step of forming the gate electrode and the lower electrode, a plurality of apertures are formed in the lower electrode.

14. The method of manufacturing the liquid crystal display device, as claimed in claim 9, wherein in the step of forming the gate electrode and the lower electrode, a plurality of apertures are formed in the lower electrode, and in the step of forming the insulating film, irregularities reflecting a shape of the lower electrode are formed on a top face of a part corresponding to an area immediately below the pixel electrode in the insulating film.
